(19) United States
(12) Patent Application Publication
(10) Pub. No.: US 2006/0169976 A1
(43) Pub. Date: Aug. 3, 2006

(54) Semiconductor device

(75) Inventors: Mitsuhiro Kameda, Kanagawa (JP); Makoto Yokota, Kanagawa (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: Kabushiki Kaisha Toshiba, Minato-ku (JP)

(21) Appl. No.: 11/325,546

(22) Filed: Jan. 5, 2006

(30) Foreign Application Priority Data
Jan. 7, 2005 (JP) 2005-2037
Dec. 28, 2005 (JP) 2005-377247

(51) Int. Cl. H01L 29/10

(52) U.S. Cl. 257/44

(57) ABSTRACT

A semiconductor device comprises: a first semiconductor chip having a first MIS transistor of a first conductivity type and a second semiconductor chip having a second MIS transistor of the first conductivity type. The first MIS transistor has a source electrode formed on a first face. The second MIS transistor has a drain electrode formed on a first face. The source electrode of the first semiconductor chip and the drain electrode of the second semiconductor chip are bonded opposite to each other.

### CROSS-REFERENCE TO RELATED APPLICATIONS

This application is based upon and claims the benefits of priorities from the prior Japanese Patent Application No. 2005-002037, filed on Jan. 7, 2005, and the prior Japanese Patent Application No. 2005-377247, filed on Dec. 28, 2005; the entire contents of which are incorporated herein by reference.

### BACKGROUND OF THE INVENTION

1. Field of the Invention

This invention relates to chip-to-chip interconnection of a semiconductor device having a plurality of semiconductor chips therein, such as interconnection between high-side and low-side power devices of a DC-DC converter.

2. Background Art

Semiconductor devices having a plurality of semiconductor chips therein are used, for example, in direct current/direct current converters (hereinafter referred to as DC-DC converters) for synchronous rectification or the like and in three-phase motors.

For example, high efficiency of a DC-DC converter requires speedup of the high-side power device to reduce the switching loss. To this end, conventionally, the capacitance and gate resistance of the high-side power device have been reduced to increase its speed. However, as power devices become faster, the high-side power device generates noise during switching, which causes a serious problem.

For instance, when an LD (Lateral Double-diffusion)-MIS (Metal Insulator Semiconductor) (including MOS (Metal Oxide Semiconductor)) transistor, designed for high-speed switching applications, is used on the high side, noise due to its inductance may conflict with the EMC (electromagnetic compatibility) regulations. Conventionally, in the case of power MISFETs, for example, reduction of inductance beneath the source of a high-side power MISFET is addressed through the use of thick and short wiring on the substrate.

One of the solutions is disclosed in JP 2003-332518A, where a semiconductor module includes a supporting substrate having a conductive connecting section. A first and a second semiconductor chip have a first and a second MIS transistor structure, respectively. The source of the first MIS transistor and the drain of the second MIS transistor are formed on the bottom of the first and second semiconductor chip, respectively. The first and second semiconductor chip are provided on the supporting substrate so that the source of the first semiconductor chip and the drain of the second semiconductor chip contact the connecting section, respectively. The source of the first semiconductor chip is electrically connected to the drain of the second semiconductor chip via the connecting section. An insulative envelope covers the supporting substrate and the first and second semiconductor chip. An external connection terminal, which is partly exposed from the envelope, is electrically connected to the connecting section and the first and second semiconductor chip. Thus a plurality of semiconductor chips are mounted on a single supporting substrate, and the source of one semiconductor chip is electrically connected to the drain of another to reduce wiring inductance. It is therefore possible to provide a semiconductor module having a plurality of semiconductor chips that can achieve downsizing and speedup.

In JP 2002-57278A, which relates to a tuner device, two semiconductor chips are mounted on both sides of a print substrate. The semiconductor chips can be placed generally at the same location on both sides of the print semiconductor substrate to decrease the chip-to-chip wiring length, thereby reducing the chip-to-chip inductance.

### SUMMARY OF THE INVENTION

According to an aspect of the invention, there is provided a semiconductor device comprising:

a first semiconductor chip having a first MIS transistor of a first conductivity type, the first MIS transistor having a source electrode formed on a first face; and

a second semiconductor chip having a second MIS transistor of the first conductivity type, the second MIS transistor having a drain electrode formed on a first face, wherein

the source electrode of the first semiconductor chip and the drain electrode of the second semiconductor chip are bonded opposite to each other.

According to other aspect of the invention, there is provided a semiconductor device comprising:

a first semiconductor chip having a first MIS transistor of a first conductivity type, the first MIS transistor having a source electrode formed on a first face and a drain electrode formed on a second face opposite to the first face;

a second semiconductor chip having a second MIS transistor of the first conductivity type, the second MIS transistor having a drain electrode formed on a first face;

a lead frame, the source electrode of the first MIS transistor being bonded on one face of the lead frame whereby the first semiconductor chip is mounted, and the drain electrode of the second MIS transistor being bonded on the other face of the lead frame whereby the second semiconductor chip is mounted; and

a first lead bonded opposite to the drain electrode of the first MIS transistor.

According to other aspect of the invention, there is provided a semiconductor device comprising:

a first semiconductor chip having a first MIS transistor of a first conductivity type, the first MIS transistor having a source electrode formed on a first face and a drain electrode formed on a second face opposite to the first face;

a second semiconductor chip having a second MIS transistor of the first conductivity type, the second MIS transistor having a drain electrode formed on a first face;

a first lead frame, the source electrode of the first MIS transistor being bonded on one face of the first lead frame whereby the first semiconductor chip is mounted, and the drain electrode of the second MIS transistor being bonded on the other face of the first lead frame whereby the second semiconductor chip is mounted;

a first lead bonded opposite to the drain electrode of the first MIS transistor;

a control IC for controlling operation of the first MIS transistor and the second MIS transistor; and

a resin sealant for sealing the first semiconductor chip, the second semiconductor chip, and the control IC.

### BRIEF DESCRIPTION OF THE DRAWINGS

FIG. 1 is a cross section of a semiconductor device of a first example of the invention in which the source of a first semiconductor chip is bonded opposite to the drain of a second semiconductor chip.

FIG. 2 is a perspective view showing the appearance of the semiconductor device of FIG. 1.

FIG. 3 is a plan view showing the upper face inside the resin sealant of the semiconductor device of FIG. 1.

FIG. 4 is a plan view showing the lower face inside the resin sealant of the semiconductor device of FIG. 1.

FIG. 5 is a cross section of an LD-MIS transistor formed in the first semiconductor chip for use in the semiconductor device of FIG. 1.

FIG. 6 is a cross section of a D-MIS transistor formed in the second semiconductor chip for use in the semiconductor device of FIG. 1.

FIG. 7 is a circuit diagram of a DC-DC converter, which is a semiconductor device that illustrates the invention.

FIG. 8 is a cross section of a semiconductor device of a second example of the invention in which the source of a first semiconductor chip is bonded opposite to the drain of a second semiconductor chip.

FIGS. 9A, 9B, 10A and 10B are cross sections of a semiconductor device of a third example of the invention in which the drain-source of a first semiconductor chip is bonded opposite to the drain of a second semiconductor chip.

FIG. 11 is a cross section of a semiconductor device of a fourth example of the invention in which the source of a first semiconductor chip is bonded opposite to the drain of a second semiconductor chip.

FIGS. 12A and 12B are a cross section showing a D-MIS transistor and an LD-MIS transistor of a fifth example of the invention.

FIG. 13 is a circuit diagram illustrating the configuration of a DC-DC converter.

FIG. 14 is a cross section schematically illustrating the cross-sectional structure of the relevant part of a semiconductor device of a sixth example mounted on a print wiring board.

FIG. 15 is a top view of the semiconductor device shown in FIG. 14 where the heat radiating plate is removed.

FIG. 16 is a bottom view of the semiconductor device of the sixth example.

FIG. 17 is a plan view showing the internal structure of the semiconductor device of the sixth example.

FIG. 18 is a plan view showing the internal structure of a semiconductor device of a seventh example of the invention.

FIG. 19 is a plan view showing the internal structure of a semiconductor device of an eighth example of the invention.

FIG. 20 is a plan view showing the internal structure of a semiconductor device of a ninth example of the invention.

FIG. 21 is a plan view schematically showing the lower (bottom) face of a semiconductor device of a tenth example of the invention.

FIG. 22 is a plan view showing the internal structure of a semiconductor device of an eleventh example of the invention.

FIG. 23 is a cross section schematically illustrating the cross-sectional structure of the relevant part of a semiconductor device of a twelfth example of the invention.

FIG. 24 is a plan view showing the internal structure of the semiconductor device of the twelfth example.

FIG. 25 is a cross section schematically illustrating the cross-sectional structure of the relevant part of a semiconductor device of a thirteenth example of the invention.

FIG. 26 is a plan view showing the internal structure of the semiconductor device of the thirteenth example.

FIG. 27 is a graph showing a dependence of a conversion efficiency on each parasitic inductance L_{hd}, Lₕₛ, L_{ld}, Lₗₛ, L_{hg}, L_{lg} in the DC-DC converter shown in FIG. 13.

FIG. 28 is a waveform chart showing a time change of the voltage (driver output) (V_{g-Lx}) between the gate of the first MIS transistor Q1 and the node Lₓ, the gate-source voltage (actual g-s voltage) (V_{gs}), and the voltage drop (V_{Lhs}) in parasitic inductance Lₕₛ.

FIGS. 29A and 29B are a waveform chart showing a time change of the power consumption, the gate-source voltage (V_{gs}), the drain-source voltage (V_{ds}) and the drain current (Id) on the first MIS transistor (high side MOS) Q1 switching with Lₕₛ=0.44, 1.24 [nH].

FIG. 30 is a graph showing a dependence of a conversion efficiency on each parasitic inductance L_{hd}, Lₕₛ, L_{ld}, Lₗₛ, L_{hg}, L_{lg} in the DC-DC converter shown in FIG. 13.

FIGS. 31A and 31B are a waveform chart showing a time change of the power consumption, the gate-source voltage (V_{gs}), the drain-source voltage (V_{ds}) and the drain current (Id) on the first MIS transistor (high side MOS) Q1 switching with Lₗₛ=1.4, 5.6 [nH].

### DETAILED DESCRIPTION OF THE INVENTION

According to the invention, the drain of a MIS transistor (including MOS transistor) is opposed to the source of another MIS transistor (including MOS transistor). The transistors are bonded together via a lead as desired. The inductance of wiring between a plurality of MIS transistors is thus reduced.

Embodiments of the invention will now be described with reference to examples.

### EXAMPLES

### First Example

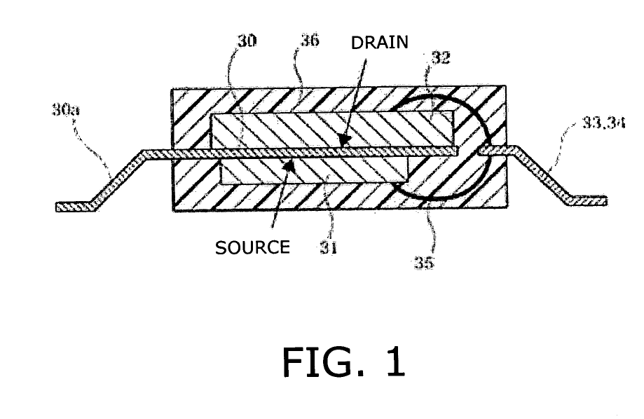

A first example is now described with reference to FIGS. 1 to 7.

FIG. 1 is a cross section of a semiconductor device in which the source of a first semiconductor chip is bonded opposite to the drain of a second semiconductor chip.

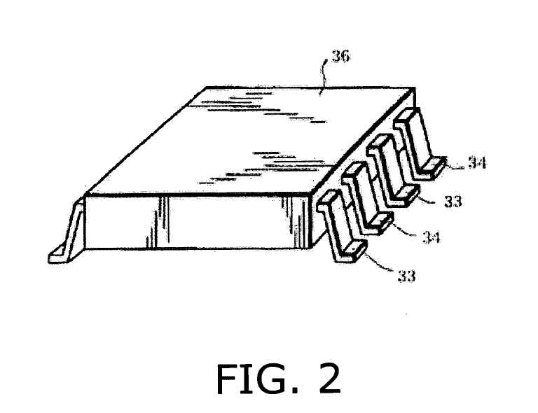

FIG. 2 is a perspective view showing the appearance of the semiconductor device of FIG. 1.

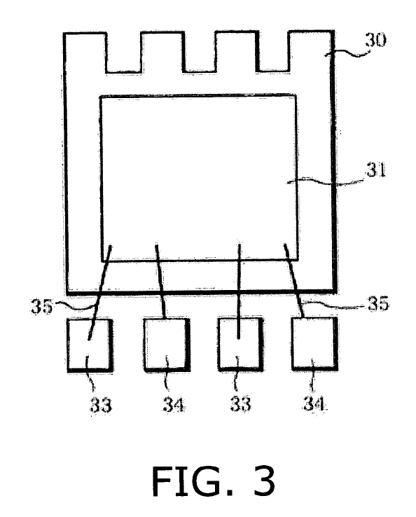

FIG. 3 is a plan view showing the upper face inside the resin sealant of the semiconductor device of FIG. 1.

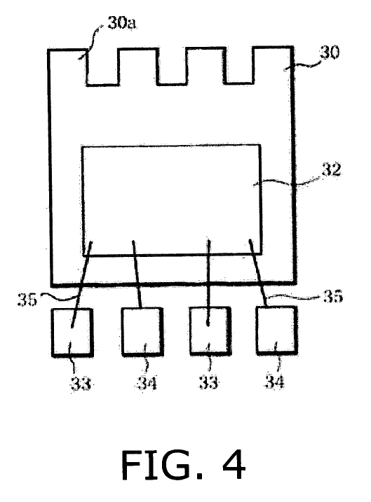

FIG. 4 is a plan view showing the lower face inside the resin sealant of the semiconductor device of FIG. 1.

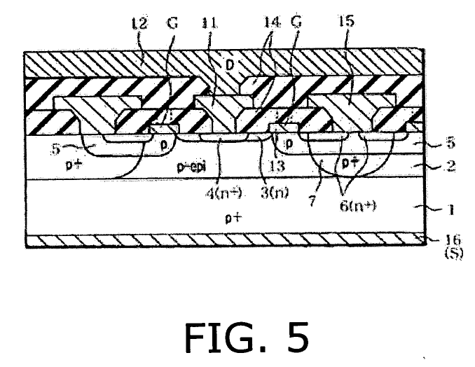

FIG. 5 is a cross section of an LD-MIS transistor formed in the first semiconductor chip for use in the semiconductor device of FIG. 1.

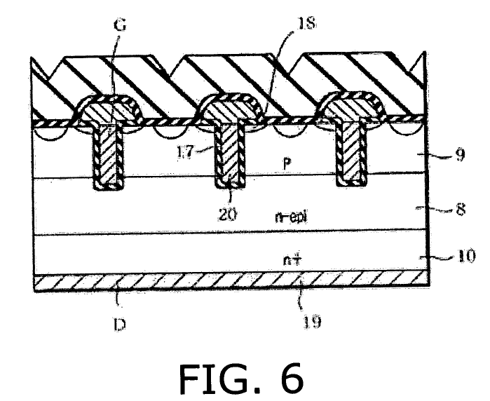

FIG. 6 is a cross section of a D(Double-diffusion)-MIS transistor formed in the second semiconductor chip for use in the semiconductor device of FIG. 1.

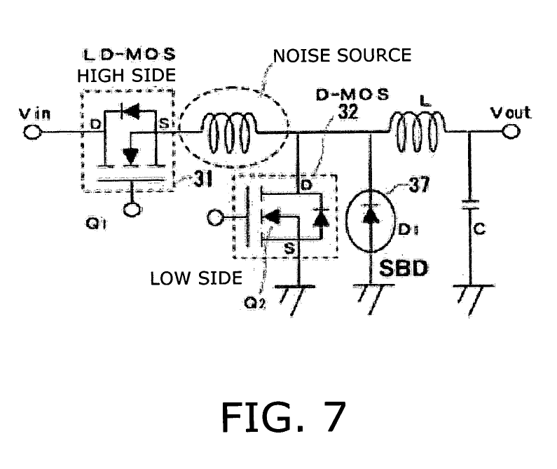

FIG. 7 is a circuit diagram of a DC-DC converter, which is a semiconductor device of this example.

By way of example, semiconductor devices having a plurality of semiconductor chips therein include DC-DC converters and three-phase motors. The present example, as well as the subsequent examples, will be described with reference to a DC-DC converter.

First, reference is made to FIGS. 1 to 4 to describe the assembled structure of semiconductor chips.

A first semiconductor chip 31 used in this example comprises an LD-MIS transistor (Q1). The source formed on the bottom face of the first semiconductor chip 31 is bonded to a lead frame 30 made of conductor such as copper or copper alloy. Likewise, a second semiconductor chip 32 used in this example comprises a D-MIS transistor (Q2). The drain formed on the bottom face of the second semiconductor chip 32 is bonded to the lead frame 30. In other words, the first semiconductor chip 31 is placed opposite to the second semiconductor chip 32 via the lead frame 30.

A lead terminal 30a formed at one end of the lead frame 30 is used as an output terminal via an inductance (L in FIG. 7) of the DC-DC converter. Lead terminals 33 and 34 are formed at the other end of the lead frame 30. The lead terminal 33 is connected via a bonding wire 35 to the gate or drain of the first semiconductor chip 31 to be used as a gate or drain terminal. The lead terminal 34 is connected via the bonding wire 35 to the gate or source of the second semiconductor chip 32 to be used as a gate or source terminal. Two or more terminals may be provided as the drain terminal 33 of the first semiconductor chip 31 and the source terminal 34 of the second semiconductor chip 32 to interconnect the drain and source via two or more bonding wires, respectively. A plurality of bonding wires can be connected to a single source or drain to prevent excessive current concentration and to reduce the resistive component. Alternatively, instead of using bonding wires, it is also possible to use a ribbon-shaped metal plate especially for the source or drain for reducing the resistive component and for preventing excessive current concentration.

FIGS. 1 and 2 illustrating this example show the D-MIS transistor (second semiconductor chip) above and the LD-MIS transistor (first semiconductor chip) below. However, they may be turned upside down, using the LD-MIS transistor (first semiconductor chip) above and the D-MIS transistor (second semiconductor chip) below. This is also applicable to the other examples and variations. The portion of the lead frame 30 mounted on the chip, the semiconductor chips 31 and 32, and the bonding wire 35 are sealed with a resin sealant 36 made of epoxy resin or the like.

FIG. 7 is a circuit diagram showing the configuration of the DC-DC converter of this example. As shown, a capacitor (not shown) is connected between an input terminal Vᵢₙ, supplied with an input voltage, and ground (GND). The input terminal Vᵢₙ is connected to the drain of a MIS transistor Q1 having an N-type channel (current path). Note that the term MIS transistor used herein includes MOS transistors. The gate of the MIS transistor Q1 is connected to a DC-DC conversion IC (not shown). The MIS transistor Q1 functions as a switching device. The source of the MIS transistor Q1 is connected to the drain of an N-type MIS transistor Q2. The MIS transistor Q2 has a source connected to ground (GND), and a gate connected to the above-mentioned IC.

The connecting node of the source of the MIS transistor Q1 and the drain of the MIS transistor Q2 is connected to the cathode of a diode (D1) 37. The anode of the diode (D1) 37 is connected to ground (GND). The connecting node of the source of the MIS transistor Q1 and the drain of the MIS transistor Q2 is connected to an output terminal Vₒᵤₜ via inductance L, and the anode of the diode (D1) 37 is coupled to ground (GND). A capacitor C is connected in parallel between the output terminal Vₒᵤₜ and ground.

In this DC-DC converter circuit, the MIS transistor Q1 is formed in the first semiconductor chip 31 as a high-side power device, and the MIS transistor Q2 is formed in the second semiconductor chip 32 as a low-side power device. The MIS transistors in the semiconductor chips 31 and 32 have a known structure. The high-side MIS transistor Q1 uses an LD-MIS transistor (see FIG. 5), and the low-side MIS transistor Q2 uses a D-MIS transistor (see FIG. 6).

On the other hand, in the DC-DC converter circuit of FIG. 7, the source of the MIS transistor Q1 is connected to the drain of the MIS transistor Q2. Accordingly, with the lead frame 30 being used as a common potential, the source of the semiconductor chip 31 and the drain of the semiconductor chip 32 are connected to both sides of the lead frame 30, respectively (see FIGS. 3 and 4).

As described above, the source of the LD-MIS transistor Q1 and the drain of the D-MIS transistor can be mounted on opposite sides of the lead frame to reduce wiring inductance between the MIS transistors. More specifically, significant reduction is achieved in the wiring inductance, which may otherwise cause noise, between the source of the LD-MIS transistor Q1 and the drain of the D-MIS transistor. Furthermore, current flow between the transistors is made perpendicular to the lead frame, thereby decreasing the variation of current density as compared to the conventional horizontal flow of current with respect to the semiconductor chip.

Next, reference is made to FIG. 5 to describe the LD-MIS transistor constituting the high-side MIS transistor Q1. A MIS transistor having the so-called lateral structure (herein referred to as LD-MIS transistor) is known. The figure schematically shows an example structure of the LD-MIS transistor. On a p-type semiconductor substrate 1, an epitaxial (p-epi) layer 2 is formed by epitaxial growth, for example. Ion implantation, for example, is used to form an n-layer (impurity diffusion region) 3 in the surface of the epitaxial layer 2. Likewise, an n⁺-layer (impurity diffusion region) 4 having a higher concentration than the n-layer 3 is formed in the n-layer 3. P-layers (impurity diffusion regions) 5 are formed at both ends of the n-layer 3 in the epitaxial layer 2. N⁺-layers (impurity diffusion regions) 6 are formed in the p-layer 5 with a predetermined spacing therebetween. A p⁺-layer (impurity diffusion region) 7 is formed to extend from the n⁺-layer 6 to the semiconductor substrate 1.

A drain electrode (D) 12 is formed, via an interconnect layer 11 made of conductive material, at a position corresponding to the n⁺-layer 4 above the epitaxial layer 2. A gate electrode (G) 13 is formed at a position corresponding to the region between the n-layer 3 and the n⁺-layer 6 above the epitaxial layer 2. The interconnect layer 11 and the gate electrode 13 are connected to each other via an interlayer insulating film 14. A contact layer 15 is formed at a position corresponding to the region between the n⁺-layers 6 in the p-layer above the epitaxial layer 2. The contact layer 15 is electrically connected via the p⁺-layer 7 to a source electrode (S) 16 formed entirely on the bottom surface of the semiconductor substrate 1. Note that such a lateral MIS transistor structure is illustrative only. It is to be understood that any other form of MIS transistor can be used.

Next, reference is made to FIG. 6 to describe the D-MIS transistor constituting the low-side MIS transistor Q2. The MIS transistor Q2 has an n-type, vertical MIS transistor structure, for example, and is formed in the semiconductor chip 32 having a drain on its bottom face. The figure schematically shows an example structure of the D-MIS transistor. On an n-type semiconductor substrate 10, an epitaxial (n-epi) layer 8 is formed by epitaxial growth, for example. Trenches are formed in the surface region of the epitaxial layer 8. A gate insulating film 17 such as silicon oxide film or silicon nitride film is formed on the trench surface, and a gate electrode 20 (G) such as polysilicon is buried inside the trench. Ion implantation, for example, is used to form a p-layer (impurity diffusion region) 9 in the surface of the epitaxial layer 8. Likewise, an n-layer (impurity diffusion region) 18 is formed in the p-layer 9 to surround the trench surface region. The n-layer 18 serves as a source region. A drain electrode (D) 19 made of gold or the like is formed on the bottom face of the semiconductor substrate 10. The semiconductor substrate 10 is thus used as a drain region.

As described above, both the LD-MIS transistor and the D-MIS transistor are bonded opposite to each other on both sides of the lead frame. These transistors are bonded to the lead frame 30 via the source electrode 16 and the drain electrode 19.

### Second Example

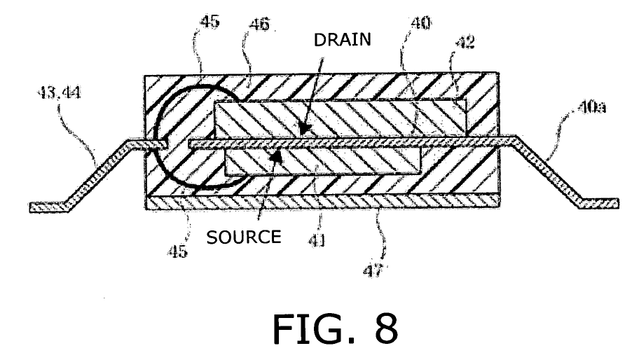

Next, a second example is described with reference to FIG. 8.

FIG. 8 is a cross section of a semiconductor device in which the source of a first semiconductor chip is bonded opposite to the drain of a second semiconductor chip. This example is described with reference to a DC-DC converter (see FIG. 7). This example is characterized in that a heat radiating plate is added to the resin sealant of the semiconductor device.

A first semiconductor chip 41 used in this example comprises an LD-MIS transistor (see FIG. 5). The source formed on the bottom face of the first semiconductor chip 41 is bonded to a lead frame 40 made of conductor such as copper or copper alloy. Likewise, a second semiconductor chip 42 used in this example comprises a D-MIS transistor (see FIG. 6). The drain formed on the bottom face of the second semiconductor chip 42 is bonded to the lead frame 40. In other words, the first semiconductor chip 41 is placed opposite to the second semiconductor chip 42 via the lead frame 40.

A lead terminal 40a formed at one end of the lead frame 40 is used as an output terminal (Vₒᵤₜ in FIG. 7) via an inductance (L in FIG. 7) of the DC-DC converter. Lead terminals 43 and 44 are formed at the other end of the lead frame 40. The lead terminal 43 is connected via a bonding wire 45 to the gate or drain of the first semiconductor chip 41 to be used as a gate or drain terminal. The lead terminal 44 is connected via the bonding wire 45 to the gate or source of the second semiconductor chip 42 to be used as a gate or source terminal. The drain terminal 43 of the first semiconductor chip 41 is used as an input terminal (Vᵢₙ in FIG. 7). Two or more terminals may be provided as the drain terminal 43 of the first semiconductor chip 41 and the source terminal 44 of the second semiconductor chip 42 to interconnect the drain and source via two or more bonding wires, respectively. A plurality of bonding wires can be connected to a single source or drain to prevent excessive current concentration and to reduce the resistive component. Alternatively, instead of using bonding wires, it is also possible to use a ribbon-shaped metal plate especially for the source or drain for reducing the resistive component and for preventing excessive current concentration.

FIG. 8 illustrating this example shows the D-MIS transistor (second semiconductor chip) above and the LD-MIS transistor (first semiconductor chip) below. However, they may be turned upside down, using the LD-MIS transistor (first semiconductor chip) above and the D-MIS transistor (second semiconductor chip) below.

The portion of the lead frame 40 mounted on the chip, the semiconductor chips 41 and 42, and the bonding wire 45 are sealed with a resin sealant 46 made of epoxy resin or the like. A heat radiating plate 47 made of copper or the like is formed on the lower face of the resin sealant 46. The heat radiating plate can be affixed to the upper face of the resin sealant. Alternatively, the heat radiating plate may be affixed directly to either upper or lower semiconductor chip and allow its outer portion to be exposed from the resin sealant.

FIG. 7 is a circuit diagram showing the configuration of the DC-DC converter of this example. As shown in this figure, the source of the MIS transistor Q1 (LD-MIS transistor) is connected to the drain of the MIS transistor Q2 (D-MIS transistor). Accordingly, as shown in FIG. 8, with the lead frame 40 being used as a common potential, the source of the semiconductor chip 41 and the drain of the semiconductor chip 42 are connected to both sides of the lead frame 40, respectively.

This example achieves reduction of inductance beneath the source of the high-side power device, LD-MIS transistor, of the DC-DC converter constituting the semiconductor device, thereby reducing noise during switching of the power device (in other words, significant reduction is achieved in the wiring inductance, which may otherwise cause noise, between the source of the LD-MIS transistor Q1 and the drain of the D-MIS transistor Q2). Therefore a power device having a higher speed can be used at the high side. Furthermore, current flow between the transistors is made perpendicular to the lead frame, thereby decreasing the variation of current density as compared to the conventional horizontal flow of current with respect to the semiconductor chip. Moreover, heat dissipation characteristics can be significantly improved.

### Third Example

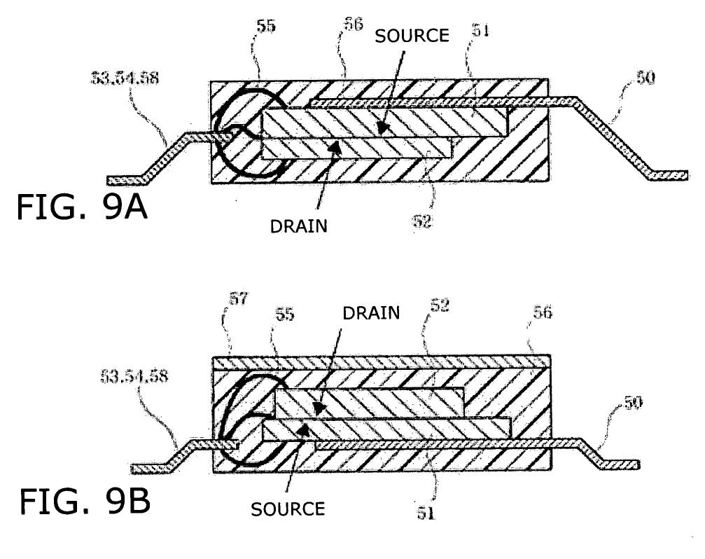

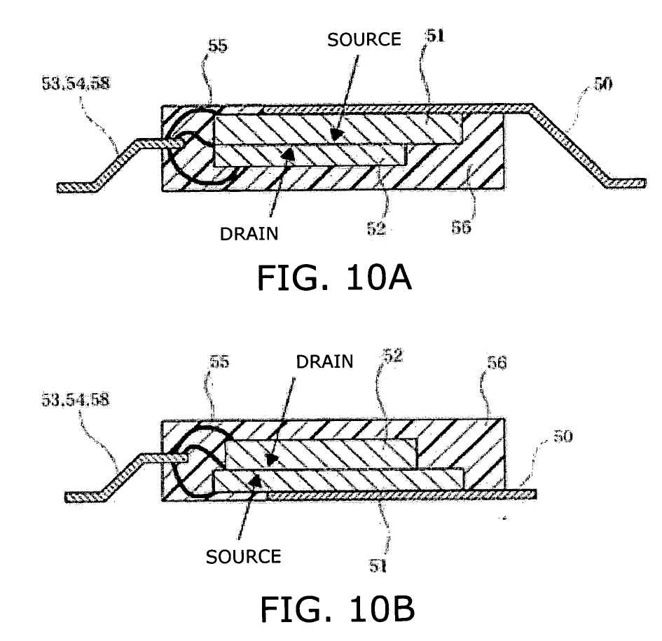

Next, a third example is described with reference to FIGS. 9 and 10.

FIGS. 9 and 10 are cross sections of a semiconductor device in which the drain-source of a first semiconductor chip is bonded opposite to the drain of a second semiconductor chip. This example is described with reference to a DC-DC converter (see FIG. 7). This example is characterized in that the first and second semiconductor chips are bonded directly to each other without using a lead frame. More specifically, the second semiconductor chip 52 comprises a D-MIS transistor (see FIG. 6). Likewise, the first semiconductor chip 51 comprises an LD-MIS transistor (see FIG. 5). The drain formed on the bottom face of the second semiconductor chip 52 is bonded directly to the source formed on the bottom face of the first semiconductor chip 51.

As shown in FIG. 9A, a lead terminal 50 is bonded to a major surface of the first semiconductor chip 51. Lead terminals 53, 54, and 58 are led out in the opposite direction of the lead terminal 50. The lead terminal 53 is connected via a bonding wire 55 to the gate of the first semiconductor chip 51 to be used as a gate terminal. The lead terminal 54 is connected via the bonding wire 55 to the gate or source of the second semiconductor chip 52 to be used as a gate or source terminal. The lead terminal 58 is connected via the bonding wire 55 to the connecting section of the source of the first semiconductor chip 51 and the drain of the second semiconductor chip 52 to be used as an output terminal of the DC-DC converter via L in FIG. 7. The drain terminal 50 of the first semiconductor chip 51 is used as an input terminal (Vᵢₙ in FIG. 7). Two or more terminals may be provided as the drain terminal 50 of the first semiconductor chip 51 and the source terminal 54 of the second semiconductor chip 52 to interconnect the drain and source via two or more bonding wires, respectively. A plurality of bonding wires can be connected to a single source or drain to prevent excessive current concentration and to reduce the resistive component. Alternatively, instead of using bonding wires, it is also possible to use a ribbon-shaped metal plate especially for the source or drain for reducing the resistive component and for preventing excessive current concentration.

FIG. 9A illustrating this example shows the D-MIS transistor (second semiconductor chip) on the opposite side of the bump connection and the LD-MIS transistor (first semiconductor chip) on the bump connection side. However, they may be turned upside down, using the LD-MIS transistor (first semiconductor chip) on the opposite side of the bump connection and the D-MIS transistor (second semiconductor chip) on the bump connection side.

The first and second semiconductor chip 51 and 52, the bonding wire 55, and part of the lead terminals are sealed with a resin sealant 56 made of epoxy resin or the like.

In the case of FIG. 9B, a heat radiating plate 57 is provided on the upper face of the resin sealant 56 that seals the first and second semiconductor chip 51 and 52. In this example, the heat radiating plate is placed on the upper face of the resin sealant. However, as a variation, the heat radiating plate may be provided on the lower face of the resin sealant. Alternatively, as in the variation of the second example, the heat radiating plate may be affixed directly to either the first or second semiconductor chip. The heat radiating plate can be placed as described above also in the semiconductor device in which the first semiconductor chip is placed above and the second semiconductor chip is placed below.

FIG. 10 shows an example in which no heat radiating plate is used. However, both of the semiconductor devices shown in FIGS. 10A and 10B have a configuration in which a lead terminal 50 bonded to the first semiconductor chip 51 is exposed from the resin sealant 56 to serve for heat dissipation.

This example achieves reduction of inductance beneath the source of the high-side power device, LD-MIS transistor, of the DC-DC converter constituting the semiconductor device, thereby reducing noise during switching of the power device (in other words, significant reduction is achieved in the wiring inductance, which may otherwise cause noise, between the source of the LD-MIS transistor Q1 and the drain of the D-MIS transistor Q2). Therefore a power device having a higher speed can be used at the high side. Furthermore, current flow between the transistors is made perpendicular to the lead frame, thereby decreasing the variation of current density as compared to the conventional horizontal flow of current with respect to the semiconductor chip. Moreover, heat dissipation characteristics can be significantly improved through the use of the heat radiating plate or the lead terminals having high heat dissipation.

### Fourth Example

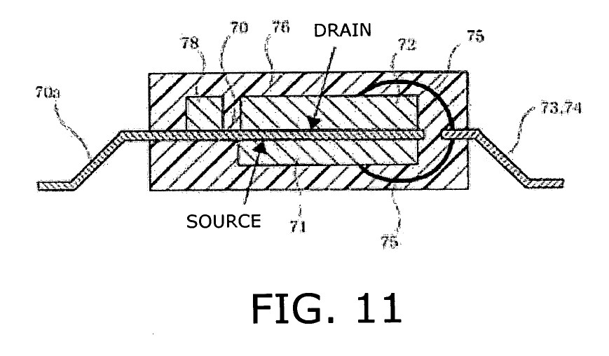

Next, a fourth example is described with reference to FIG. 11.

FIG. 11 is a cross section of a semiconductor device in which the source of a first semiconductor chip is bonded opposite to the drain of a second semiconductor chip. This example is described with reference to a DC-DC converter (see FIG. 7). This example is characterized in that a DC-DC conversion IC connected to the DC-DC converter circuit is mounted on a lead frame as a separate semiconductor chip other than the two semiconductor chips and sealed in the resin sealant. The DC-DC converter (see FIG. 7) functions by the addition of the conversion IC. The conversion IC is connected to the gate of the MIS transistor Q1 of the first semiconductor chip and the gate of the MIS transistor Q2 of the second semiconductor chip.

The first semiconductor chip 71 comprises an LD-MIS transistor (see FIG. 5). The source formed on the bottom face of the first semiconductor chip 71 is bonded to a lead frame 70 made of conductor such as copper or copper alloy. The second semiconductor chip 72 comprises a D-MIS transistor (see FIG. 6). The drain formed on the bottom face of the second semiconductor chip 72 is bonded to the lead frame 70. In other words, the first semiconductor chip 71 is placed opposite to the second semiconductor chip 72 via the lead frame 70.

The conversion IC chip 78 is bonded on the upper face of the lead frame 70 alongside the second semiconductor chip 72. In this case, the conversion IC chip 78 is mounted on the lead frame 70 with its bottom face being insulated.

A lead terminal 70a formed at one end of the lead frame 70 is used as an output terminal (Vₒᵤₜ in FIG. 7) of the DC-DC converter. Lead terminals 73 and 74 are formed at the other end of the lead frame 70. The lead terminal 73 is connected via a bonding wire 75 to the gate or drain of the first semiconductor chip 71 to be used as a gate or drain terminal. The lead terminal 74 is connected via the bonding wire 75 to the gate or source of the second semiconductor chip 72 to be used as a gate or source terminal. Two or more terminals may be provided as the drain terminal 73 of the first semiconductor chip 71 and the source terminal 74 of the second semiconductor chip 72 to interconnect the drain and source via two or more bonding wires, respectively. A plurality of bonding wires can be connected to a single source or drain to prevent excessive current concentration and to reduce the resistive component. Alternatively, instead of using bonding wires, it is also possible to use a ribbon-shaped metal plate especially for the source or drain for reducing the resistive component and for preventing excessive current concentration.

FIG. 11 illustrating this example shows the D-MIS transistor (second semiconductor chip) above and the LD-MIS transistor (first semiconductor chip) below. However, they may be turned upside down, using the LD-MIS transistor (first semiconductor chip) above and the D-MIS transistor (second semiconductor chip) below. The conversion IC 78 may be formed above the lead frame 70 as in this example, or may be formed below the lead frame.

The gate of the MIS transistor Q1 is connected to the conversion IC 78. The MIS transistor Q1 functions as a switching device. The source of the MIS transistor Q1 is connected to the drain of the N-type MIS transistor Q2. The MIS transistor Q2 has a source connected to ground (GND), and a gate connected to the above-mentioned IC 78 (see FIG. 7).

The portion of the lead frame 70 mounted on the chip, the semiconductor chips 71 and 72, and the bonding wire 75 are sealed with a resin sealant 76 made of epoxy resin or the like.

A heat radiating plate may be provided on the upper or lower face of the resin sealant. Alternatively, the heat radiating plate may be affixed directly to either upper or lower semiconductor chip and allow its outer portion to be exposed from the resin sealant.

FIG. 7 is a circuit diagram showing the configuration of the DC-DC converter of this example. As shown in this figure, the source of the MIS transistor Q1 (LD-MIS transistor) is connected to the drain of the MIS transistor Q2 (D-MIS transistor). Accordingly, as shown in FIG. 11, with the lead frame 70 being used as a common potential, the source of the semiconductor chip 71 and the drain of the semiconductor chip 72 are connected to both sides of the lead frame 70, respectively.

This example achieves reduction of inductance beneath the source of the high-side power device, LD-MIS transistor, of the DC-DC converter constituting the semiconductor device, thereby reducing noise during switching of the power device (in other words, significant reduction is achieved in the wiring inductance, which may otherwise cause noise, between the source of the LD-MIS transistor Q1 and the drain of the D-MIS transistor Q2). Therefore a power device having a higher speed can be used at the high side. Furthermore, current flow between the transistors is made perpendicular to the lead frame, thereby decreasing the variation of current density as compared to the conventional horizontal flow of current with respect to the semiconductor chip. Moreover, heat dissipation characteristics can be significantly improved. Furthermore, the number of parts of the semiconductor device can be decreased by sealing the IC chip in the resin sealant. It is to be understood that the position of the IC chip 78 is not limited to the position shown in FIG. 11.

### Fifth Example

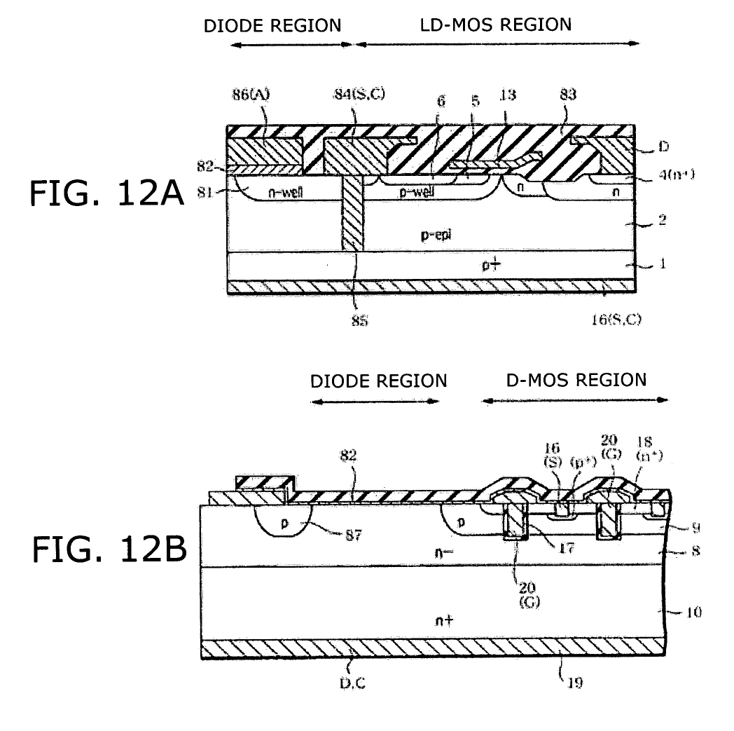

Next, a fifth example is described with reference to FIG. 12.

FIG. 12 is a cross section showing a D-MIS transistor and an LD-MIS transistor. The foregoing examples make no reference to the location of the diode D1 shown in FIG. 7. This example is characterized in that the diode D1 is formed in either of the first and second semiconductor chip.

FIG. 12A shows an example in which the LD-MIS transistor and the diode D1 are formed in the same semiconductor substrate. The reference numerals are in common with those in FIG. 6.

The LD-MIS transistor is formed in the first semiconductor chip 31 as shown in FIG. 7. The diode D1 is built into the first semiconductor chip 31. A Schottky barrier diode (SBD), for example, is used as the diode D1.

Above an n-well layer 81 in the region where the diode is to be formed (diode), the anode electrode A of the diode D1 is formed via a barrier metal 82. Besides the anode electrode (A) 86, the cathode (C) 84 of the diode D1 is provided via a silicon oxide film 83. The cathode 84 is in common with the source electrode (S) 16 of the MIS transistor (LD-MIS). This cathode-source (C, S) 84 is connected to the cathode-source electrode (S, C) 16 via a connecting layer 85.

In this way, the diode D1 constituting the DC-DC converter is built into the first semiconductor chip.

The D-MIS transistor in FIG. 12B is formed in the second semiconductor chip 32 as shown in FIG. 7. The diode D1 is built into the second semiconductor chip 32. A Schottky barrier diode (SBD), for example, is used as the diode D1.

A p-layer (impurity diffusion region) 87 is formed, away from the p-layer 9, in the surface region of the epitaxial layer 8 formed on the surface of the semiconductor substrate 10. The junction region between the epitaxial layer 8 and the barrier metal 82 constitutes the diode D1, the cathode C of which is in common with the drain (D) 19 of the D-MIS transistor.

As described above, the number of semiconductor chips constituting the semiconductor device can be further decreased by forming the diode D1 in either of the first and second semiconductor chip, as compared to providing the diode D1 as a separate semiconductor chip. Furthermore, the conversion efficiency of the DC-DC converter can be improved.

It is to be understood that forming the diode D1 in either of the first and second semiconductor chip to constitute a DC-DC converter as described in this example is also applicable to any semiconductor chip in the other examples.

### Sixth Example

Next, a sixth example of the invention is described.

A semiconductor device of this example is used, for example, as a synchronous rectification DC-DC converter. A DC-DC converter converts its input voltage into a desired value for output. While this example is described with reference to a step-down converter that lowers the output voltage, the invention is also applicable to a step-up converter.

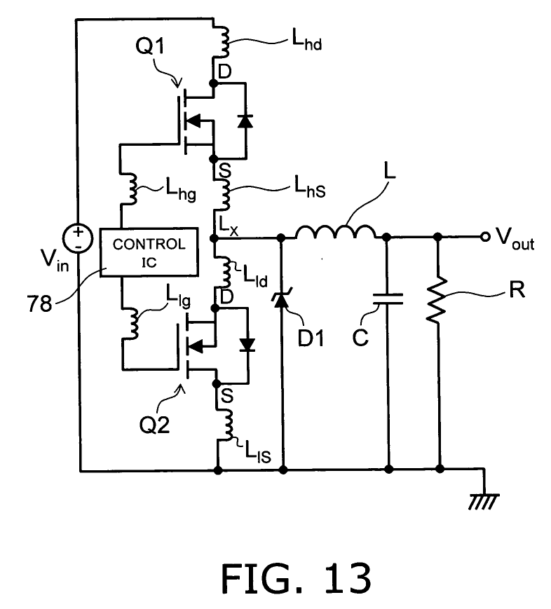

FIG. 13 is a circuit diagram illustrating the configuration of the DC-DC converter.

The drain of a first MIS transistor Q1 having an N-type channel (current path) is connected to an input voltage supply Vᵢₙ. The gate of the first MIS transistor Q1 is connected to a control IC 78. The first MIS transistor Q1 functions as a switching device under a gate driving signal from the control IC 78. The source of the first MIS transistor Q1 is connected to the drain of a second MIS transistor Q2.

The source of the second MIS transistor Q2 having an N-type channel is connected to ground (GND). The gate of the second MIS transistor Q2 is connected to the control IC 78. The second MIS transistor Q2 functions as a switching device under a gate driving signal from the control IC 78. The drain of the second MIS transistor Q2 is connected to the source of the first MIS transistor Q1.

The connecting node Lₓ of the source of the first MIS transistor Q1 and the drain of the second MIS transistor Q2 is connected to the cathode of the diode D1. The anode of the diode D1 is connected to ground (GND). The diode D1 is a Schottky barrier diode, for example.

The connecting node Lₓ is further connected to an output terminal Vₒᵤₜ via an inductor L. A capacitor C and a resistor R are connected in parallel between the output terminal Vₒᵤₜ and ground.

Note that L_{hd}, Lₕₛ, L_{ld}, Lₗₛ, L_{hg}, L_{lg} expresses a parasitic inductance.

The first MIS transistor Q1 is formed in the first semiconductor chip as a high-side (high voltage side) power device in the DC-DC converter, and the second MIS transistor Q2 is formed in the second semiconductor chip as a low-side (low voltage side) power device in the DC-DC converter. The MIS transistors in these semiconductor chips have a structure similar to those in the foregoing examples. The first MIS transistor Q1 is an LD-MIS transistor illustrated in FIG. 5, and the second MIS transistor Q2 is a D-MIS transistor illustrated in FIG. 6.

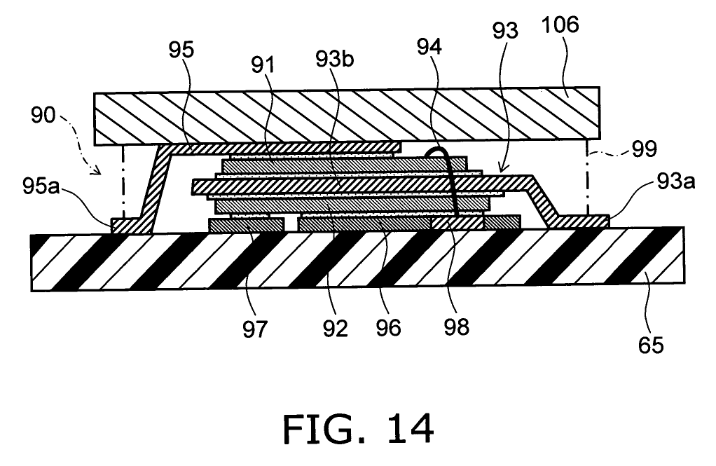

The semiconductor device of the sixth example including the above-described first and second semiconductor chip is shown in FIGS. 14 to 17.

FIG. 14 is a cross section schematically illustrating the cross-sectional structure of the relevant part of a semiconductor device 90 of this example mounted on a print wiring board 65.

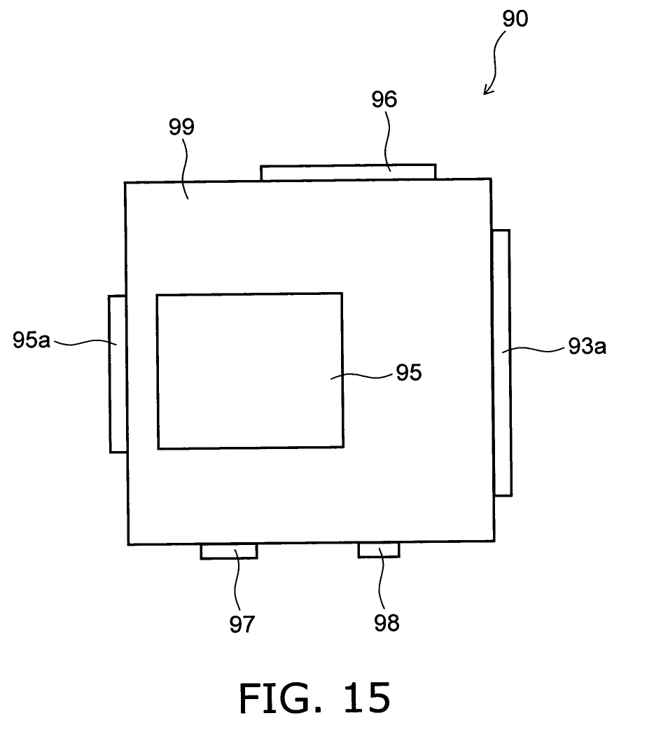

FIG. 15 is a top view of the semiconductor device 90 shown in FIG. 14 where the heat radiating plate 106 is removed.

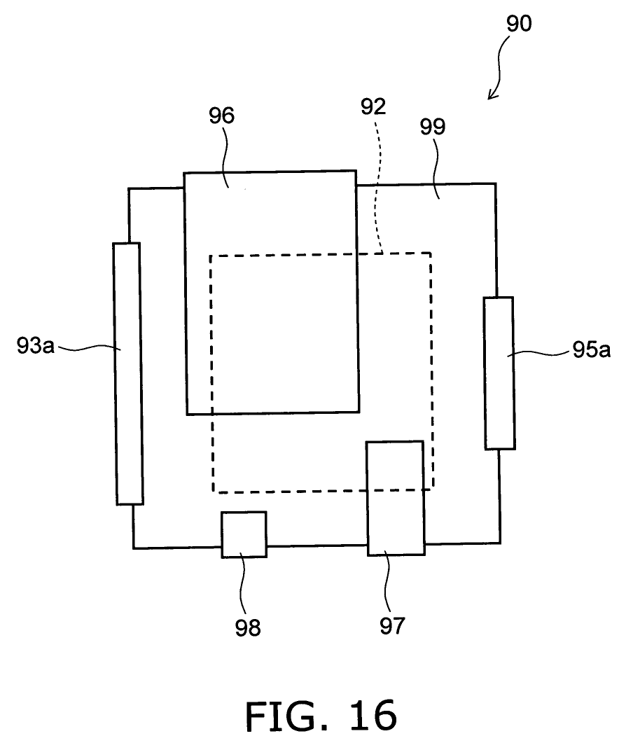

FIG. 16 is a bottom view of the semiconductor device 90.

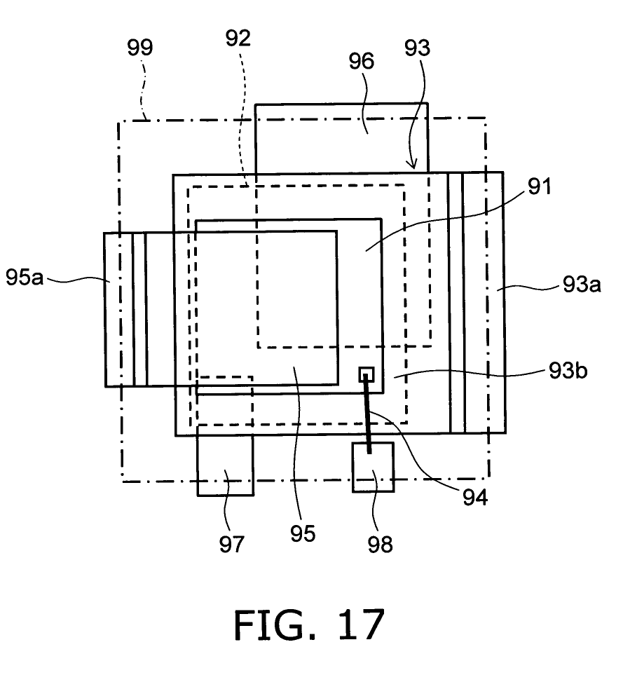

FIG. 17 is a plan view showing the internal structure of the semiconductor device 90.

The first semiconductor chip 91 includes a first MIS transistor Q1. The first semiconductor chip 91 is mounted on a lead frame 93 with its first face (lower face in FIG. 14) being opposed to one face (upper face in FIG. 14) of the island portion 93b of the lead frame 93. The lead frame 93 is made of conductor such as copper or copper alloy, for example.

The source electrode of the first MIS transistor Q1 is exposed on the first face of the first semiconductor chip 91. The source electrode is bonded to the one face of the island portion 93b of the lead frame 93 via solder, for example. The source electrode of the first MIS transistor Q1 may be bonded to the lead frame 93 by conductive bonding material other than solder, or by ultrasonic bonding that utilizes vibrational friction between the bonding surfaces due to application of ultrasonic waves. In any case, the source electrode of the first MIS transistor Q1 is preferably bonded to the lead frame 93 with low resistance.

The second semiconductor chip 92 includes a second MIS transistor Q2. The second semiconductor chip 92 is mounted on the lead frame 93 with its first face (upper face in FIG. 14) being opposed to the other face (lower face in FIG. 14) of the island portion 93b of the lead frame 93.

The drain electrode of the second MIS transistor Q2 is exposed on the first face of the second semiconductor chip 92. The drain electrode is bonded to the other face of the island portion 93b of the lead frame 93 via solder, for example. The drain electrode of the second MIS transistor Q2 may be bonded to the lead frame 93 by conductive bonding material other than solder, or by ultrasonic bonding that utilizes vibrational friction between the bonding surfaces due to application of ultrasonic waves. In any case, the drain electrode of the second MIS transistor Q2 is preferably bonded to the lead frame 93 with low resistance.

As described above, the first semiconductor chip 91 and the second semiconductor chip 92 are mounted on the top and bottom faces of the island portion 93b of the conductive lead frame 93, respectively. The source electrode of the first MIS transistor Q1 and the drain electrode of the second MIS transistor Q2 are electrically connected to each other with the lead frame 93 being used as a common potential.

The potential of the lead frame 93 corresponds to the potential of the connecting node Lₓ of the source electrode of the first MIS transistor Q1 and the drain electrode of the second MIS transistor Q2 in the circuit shown in FIG. 13. The lead frame 93 has an end portion 93a, which functions as an output terminal of the semiconductor device 90 and is connected to a wiring pattern (not shown) formed on the print wiring board 65.

The drain electrode of the first MIS transistor Q1 is exposed on a second face (upper face in FIG. 14) of the first semiconductor chip 91. A first lead 95 is bonded opposite to the second face of the first semiconductor chip 91 by ultrasonic bonding, for example, and thereby the drain electrode of the first MIS transistor Q1 is electrically connected to the first lead 95. The first lead 95 is made of conductor such as copper or copper alloy, for example. The bonding between the drain electrode of the first MIS transistor Q1 and the first lead 95 is not limited to ultrasonic bonding, but may use conductive bonding material such as solder.

The first lead 95 has an end portion 95a, which is connected to the input voltage supply Vᵢₙ shown in FIG. 13 via the wiring pattern (not shown) formed on the print wiring board 65.

A fourth lead 98 is provided on the bottom face of the semiconductor device 90. The fourth lead 98 is connected to the gate electrode of the first MIS transistor Q1 via a bonding wire 94. The fourth lead 98 is made of conductor such as copper or copper alloy, for example. The bonding wire 94 is made of gold wire, for example. As shown in FIG. 17, the fourth lead 98 is provided so as not to overlap the lead frame 93, the first semiconductor chip 91, and the second semiconductor chip 92.

On the second face of the first semiconductor chip 91, a pad portion for the gate electrode of the first MIS transistor is formed on a portion that is not used for bonding the first lead 95. One end of the bonding wire 94 is bonded to the pad portion. The other end of the bonding wire 94 is bonded to the inner face of the fourth lead 98. The fourth lead 98 is connected to the control IC 78 shown in FIG. 13 via the wiring pattern (not shown) formed on the print wiring board 65.

The source electrode of the second MIS transistor Q2 is exposed on a second face (lower face in FIG. 14) of the second semiconductor chip 92. A second lead 96 is bonded opposite to the second face of the second semiconductor chip 92 by ultrasonic bonding, for example, and thereby the source electrode of the second MIS transistor Q2 is electrically connected to the second lead 96. The second lead 96 is made of conductor such as copper or copper alloy, for example. The bonding between the source electrode of the second MIS transistor Q2 and the second lead 96 is not limited to ultrasonic bonding, but may use conductive bonding material such as solder. The second lead 96 is connected to ground via the wiring pattern (not shown) formed on the print wiring board 65.

The gate electrode of the second MIS transistor Q2 is also exposed on the second face of the second semiconductor chip 92. A third lead 97 is bonded opposite to the second face of the second semiconductor chip 92 by ultrasonic bonding, for example, and thereby the gate electrode of the second MIS transistor Q2 is electrically connected to the third lead 97. The third lead 97 is made of conductor such as copper or copper alloy, for example. The bonding between the gate electrode of the second MIS transistor Q2 and the third lead 97 is not limited to ultrasonic bonding, but may use conductive bonding material such as solder. The third lead 97 is connected to the control IC 78 shown in FIG. 13 via the wiring pattern (not shown) formed on the print wiring board 65.

The island portion 93b of the lead frame 93, the first semiconductor chip 91, the second semiconductor chip 92, and the bonding wire 94 are sealed with a resin sealant 99 such as epoxy resin, for example.

The bottom face (outer face) of the second lead 96, third lead 97, and fourth lead 98 provided on the bottom side of the semiconductor device 90 is exposed from the resin sealant 99 as shown in FIG. 16. The second lead 96, third lead 97, and fourth lead 98 are connected to the print wiring board 65 via this exposed surface.

Likewise, the end portion 95a of the first lead 95 and the end portion 93a of the lead frame 93 are also exposed from the resin sealant 99. The first lead 95 and the lead frame 93 are connected to the print wiring board 65 via this exposed surface.

Furthermore, as shown in FIG. 15, the outer face (upper face) of the first lead 95 is also exposed from the resin sealant 99. The heat radiating plate 106 shown in FIG. 14 is bonded to this exposed surface via solder, or an adhesive having high thermal conductivity, for example. The heat radiating plate 106 is made of material having high thermal conductivity such as aluminum, for example.

As described above, in this example, the source electrode of the first MIS transistor Q1 and the drain electrode of the second MIS transistor Q2 are bonded to the top and bottom faces of the conductive lead frame 93, respectively, and thereby the source electrode of the first MIS transistor Q1 and the drain electrode of the second MIS transistor Q2 are electrically connected to each other. Accordingly, the wiring length between the first MIS transistor Q1 and the second MIS transistor Q2 is decreased and the associated resistance is lowered as compared to connection via bonding wires. Therefore the parasite inductance in this wiring and the impedance due to this parasite inductance can be reduced. This allows for improvement of the conversion efficiency of the DC-DC converter and reduction of EMI (Electromagnetic Interference) noise during high-frequency operation. In this example, total parasitic inductances through a main current path can be reduced. In particular, the reduction of the parasitic inductance Lₕₛ causes the improvement of the conversion efficiency of the DC-DC converter.

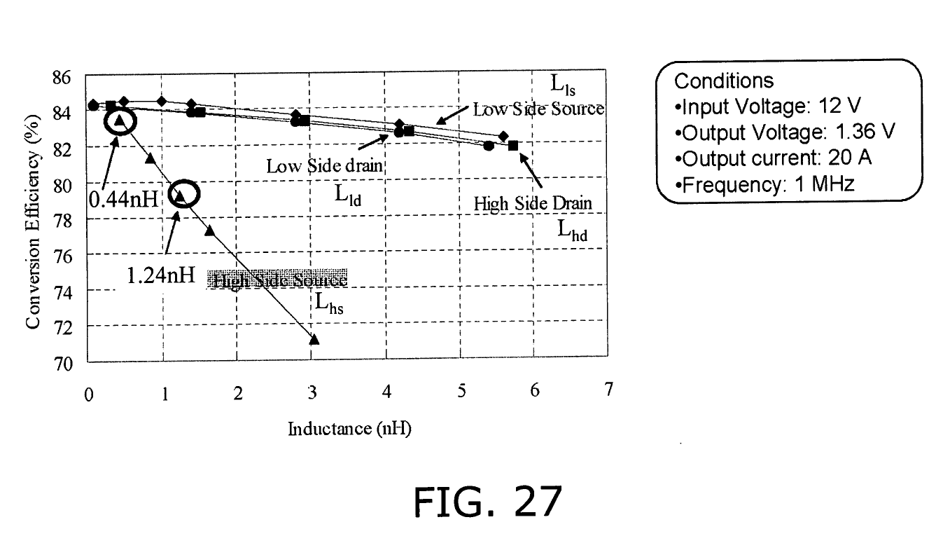

FIG. 27 shows a simulation result of a dependence of the conversion efficiency on each parasitic inductance L_{hd}, Lₕₛ, L_{ld}, Lₗₛ, L_{hg}, L_{lg} in the DC-DC converter shown in FIG. 13.

Conditions of the simulation are as follows:
Input Voltage: 12 [V]
Output Voltage: 1.36 [V]
Output current: 20 [A]
Frequency: 1 [MHz]

From FIG. 27, it is understood that the reduction of the parasitic inductance Lₕₛ is very effective for the improvement of the conversion efficiency.

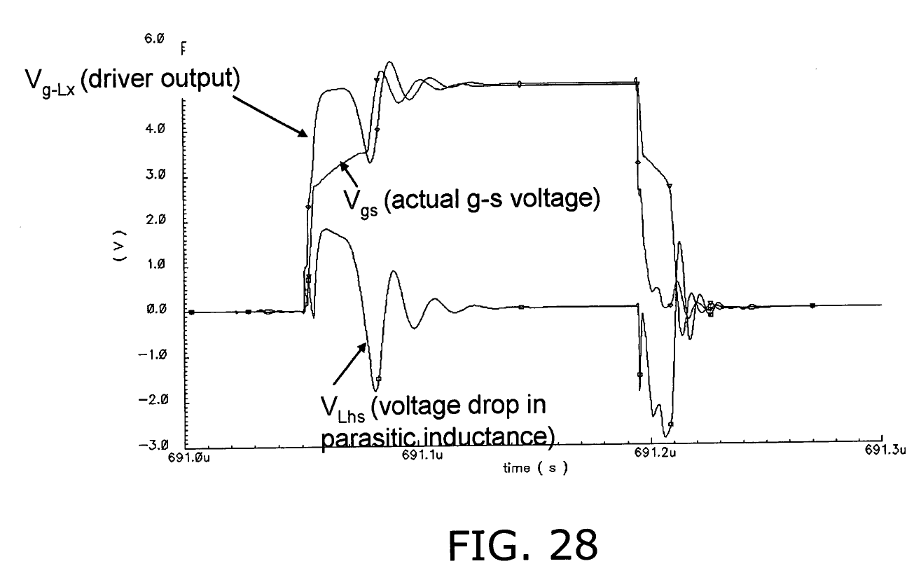

FIG. 28 shows each waveform (time change) of the voltage (driver output) (V_{g-Lx}) between the gate of the first MIS transistor Q1 and the node Lₓ, the gate-source voltage (actual g-s voltage) (V_{gs}), and the voltage drop (V_{Lhs}) in parasitic inductance Lₕₛ.

The voltage drop in the parasitic inductance Lₕₛ causes the decrease of the gate-source voltage (actual g-s voltage). Therefore, the gate-source voltage (V_{gs}) of the first MIS transistor Q1 are properly applied without the voltage drop in the parasitic inductance Lₕₛ since the parasitic inductance Lₕₛ are reduced in this example. Therefore, the drain-source voltage (V_{ds}) can be reduced during turn on period, and thereby a turn on loss can be reduced.

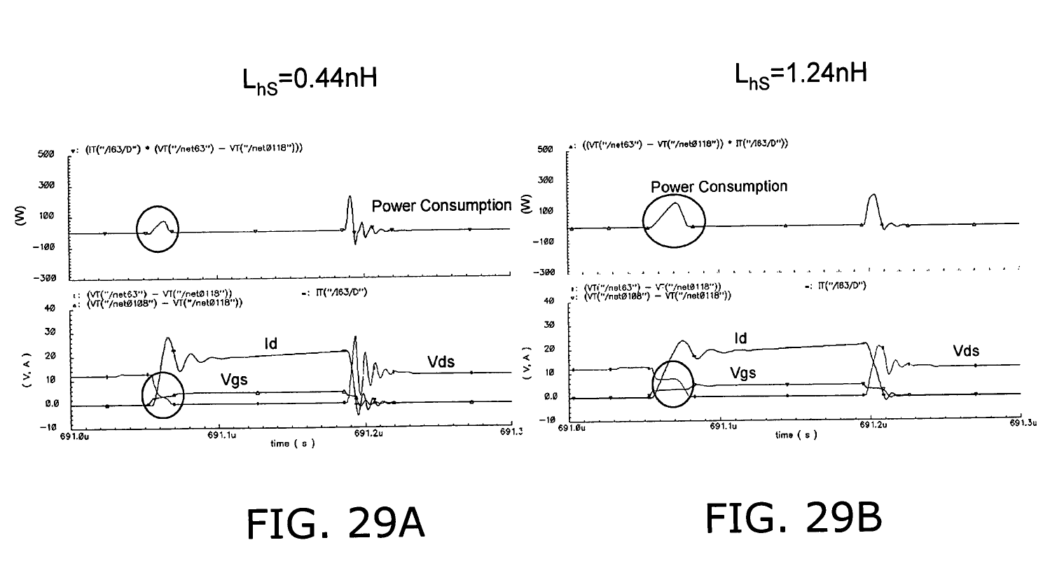

FIG. 29A shows each waveform (time change) of the power consumption, the gate-source voltage (V_{gs}), the drain-source voltage (V_{ds}) and the drain current (Id) on the first MIS transistor (high side MOS) Q1 switching with Lₕₛ=0.44[nH].

FIG. 29B shows each waveform (time change) of the power consumption, the gate-source voltage (V_{gs}), the drain-source voltage (V_{ds}) and the drain current (Id) on the first MIS transistor (high side MOS) Q1 switching with Lₕₛ=1.24[nH].

The power consumption during turn on period in the case of Lₕₛ=0.44[nH] can be lower than that in the case of Lₕₛ=1.24[nH] because of the phenomenon explained with reference to FIG. 28.

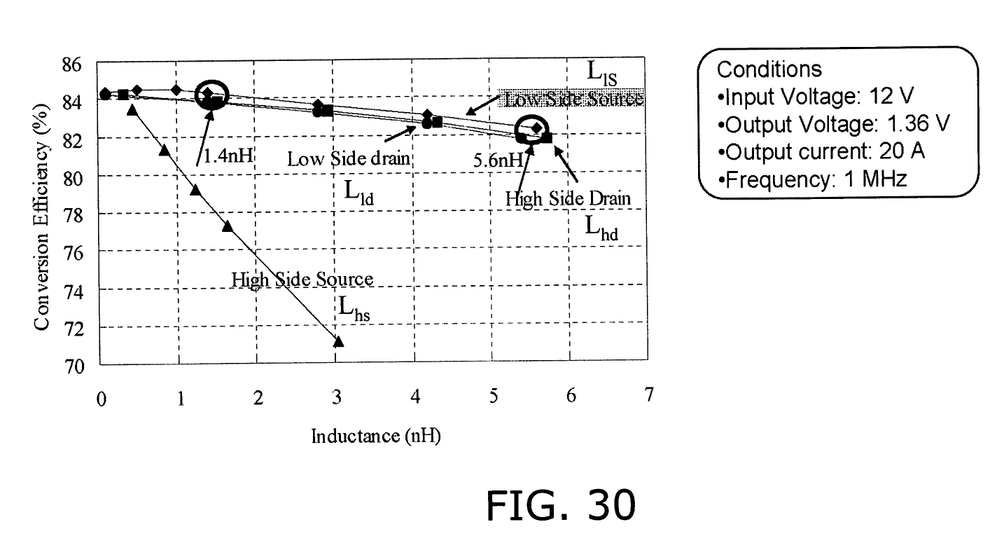

FIG. 30 shows a simulation result of a dependence of the conversion efficiency on each parasitic inductance L_{hd}, Lₕₛ, L_{ld}, Lₗₛ, L_{hg}, L_{lg} as explained with reference to FIG. 27.

Conditions of the simulation are as follows:
Input Voltage: 12 [V]
Output Voltage: 1.36 [V]
Output current: 20 [A]
Frequency: 1 [MHz]

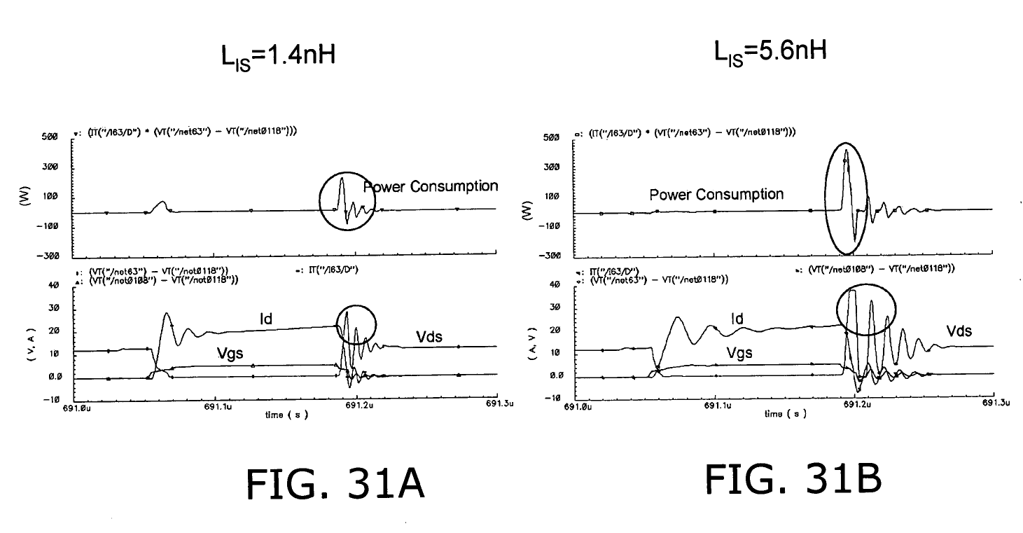

FIG. 31A shows each waveform (time change) of the power consumption, the gate-source voltage (V_{gs}), the drain-source voltage (V_{ds}) and the drain current (Id) on the first MIS transistor Q1 switching with Lₗₛ=1.4[nH].

FIG. 31B shows each waveform (time change) of the power consumption, the gate-source voltage (V_{gs}), the drain-source voltage (V_{ds}) and the drain current (Id) on the first MIS transistor Q1 switching with Lₗₛ=5.6[nH].

In the case of Lₗₛ=5.6[nH], the parasitic inductance of the second MIS transistor (low side MOS) Q2 causes a large surge drain-source voltage (V_{ds}). This causes the increase of noise and the power consumption.

Furthermore, the drain electrode of the first MIS transistor Q1 and the source and gate electrode of the second MIS transistor Q2 are led outside via the plate-like first lead 95, second lead 96, and third lead 97, respectively, instead of bonding wires, and connected to the print wiring board 65. Therefore the on-resistance can be decreased.

The reduced use of wire bonding connections allows for thinning and downscaling of the semiconductor device 90 and makes it adaptable to high-density packaging in mobile phones and notebook personal computers.

Heat generated in the operation of the first semiconductor chip 91 is dissipated outside the semiconductor device 90 via the first lead 95 and the heat radiating plate 106. This allows for excellent heat dissipation, which can improve the reliability of the first semiconductor chip 91. Furthermore, a finned heat sink can be bonded onto the heat radiating plate 106 to further enhance heat dissipation. Note that the portion exposed from the resin sealant 99 does not necessarily need to be the entire upper face of the first lead 95, but may be a part thereof. However, the larger the exposed surface, the better the heat dissipation. Heat from the second semiconductor chip 92 is dissipated via the second lead 96, the third lead 97, and the lead frame 93 and using the wiring pattern on the print wiring board 65.

Besides the second MIS transistor Q2, the diode D1 shown in FIG. 13 is also formed in the second semiconductor chip 92. The specific structure of the chip is similar to that of the fifth example described above with reference to FIG. 12. The parasite component between the wirings of the second MIS transistor Q2 and the diode D1 can also be reduced by forming the second MIS transistor Q2 and the diode D1 in the same chip.

Note that the diode D1 may be formed in the first semiconductor chip 91 together with the first MIS transistor Q1 in the case of the step-up DC-DC converter.

The first to fourth lead 95 to 98 and the end portion 93a of the lead frame 93 can be led out in arbitrary directions, respectively, and flexibly adapted to various circuit layouts.

### Seventh Example

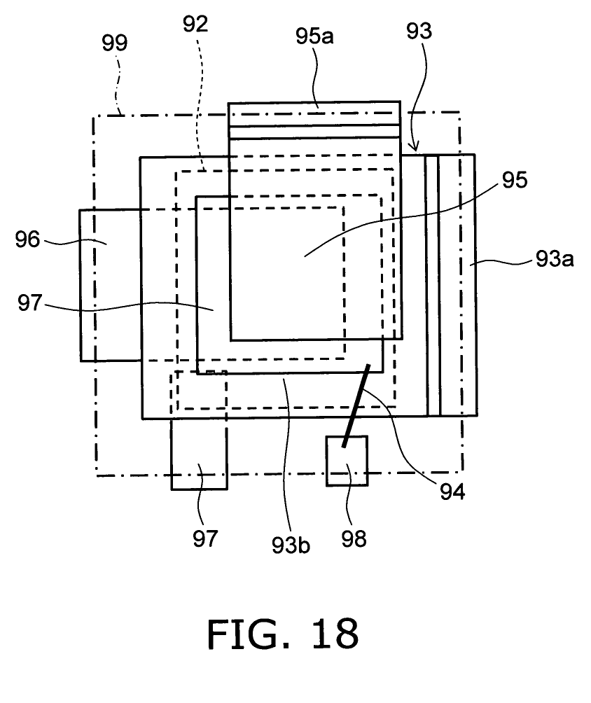

FIG. 18 is a plan view showing the internal structure of a semiconductor device of a seventh example of the invention.

In this example, the lead-out direction of the end portion 93a of the lead frame 93 and the third and fourth lead 97 and 98 is the same as that in the sixth example shown in FIG. 17. However, the end portion 95a of the first lead 95 is led out in the opposite direction of the lead-out direction of the third and fourth lead 97 and 98. The second lead 96 is led out in the opposite direction of the lead-out direction of the end portion 93a of the lead frame 93.

### Eighth Example

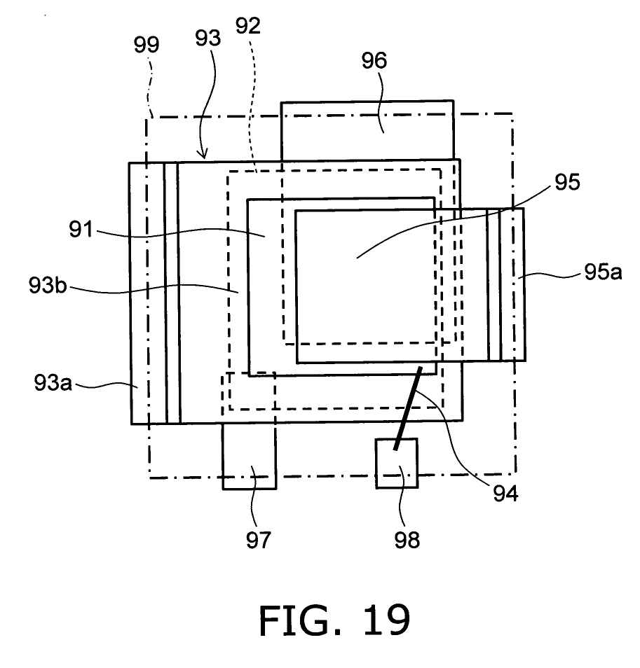

FIG. 19 is a plan view showing the internal structure of a semiconductor device of an eighth example of the invention.

In this example, the lead-out direction of the end portion 95a of the first lead 95 and the lead-out direction of the end portion 93a of the lead frame 93 are opposite to those in the sixth example shown in FIG. 17.

### Ninth Example

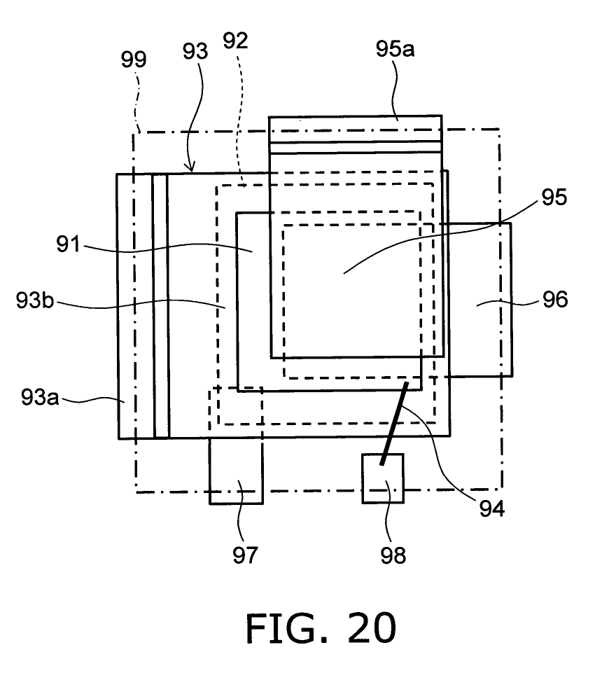

FIG. 20 is a plan view showing the internal structure of a semiconductor device of a ninth example of the invention.

In this example, the lead-out direction of the second lead 96 and the lead-out direction of the end portion 93a of the lead frame 93 are opposite to those in the seventh example shown in FIG. 18.

### Tenth Example

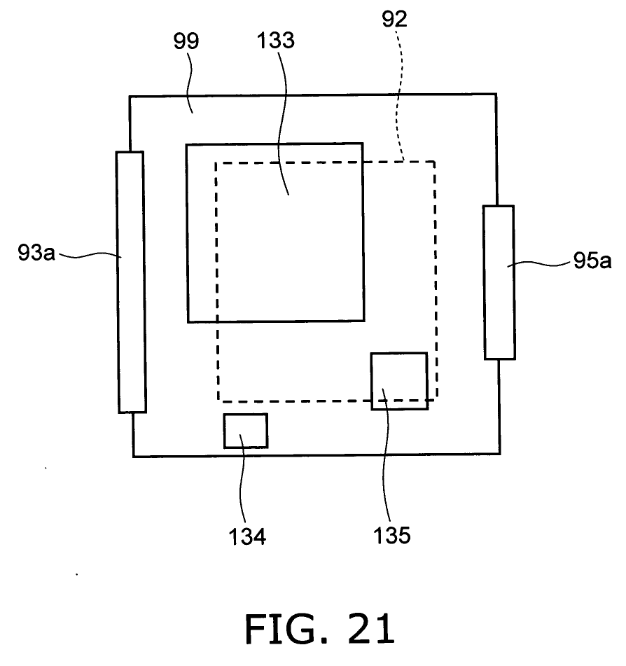

FIG. 21 is a plan view schematically showing the lower (bottom) face of a semiconductor device of a tenth example of the invention.

In this example, the second to fourth lead 133, 135, and 134 formed on the bottom face of the semiconductor device do not extend to the periphery of the semiconductor device. The second to fourth lead 133, 135, and 134 can be connected to the external circuit if they are exposed from the resin sealant 99.

However, if the second to fourth lead are formed to extend to the periphery or to protrude slightly from the periphery as in the above-described sixth example shown in FIG. 16, then it is easier to confirm the condition of solder or other bonding material, for example, which facilitates discovery of any bonding failure.

### Eleventh Example

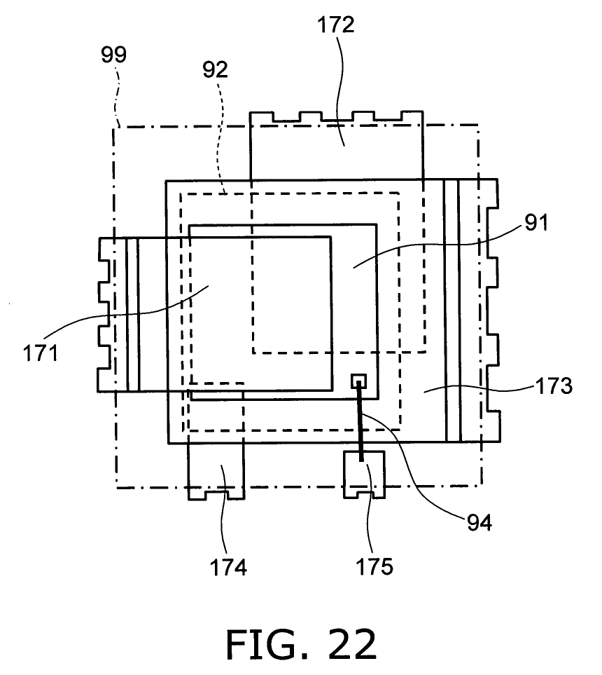

FIG. 22 is a plan view showing the internal structure of a semiconductor device of an eleventh example of the invention.

In this example, the end portion of the first lead 171, second lead 172, third lead 173, fourth lead 175, and the lead frame 173 is split into a plurality of portions.

### Twelfth Example

Next, a twelfth example of the invention is described.

The semiconductor device of this example is also used as a DC-DC converter shown in FIG. 13, for example.

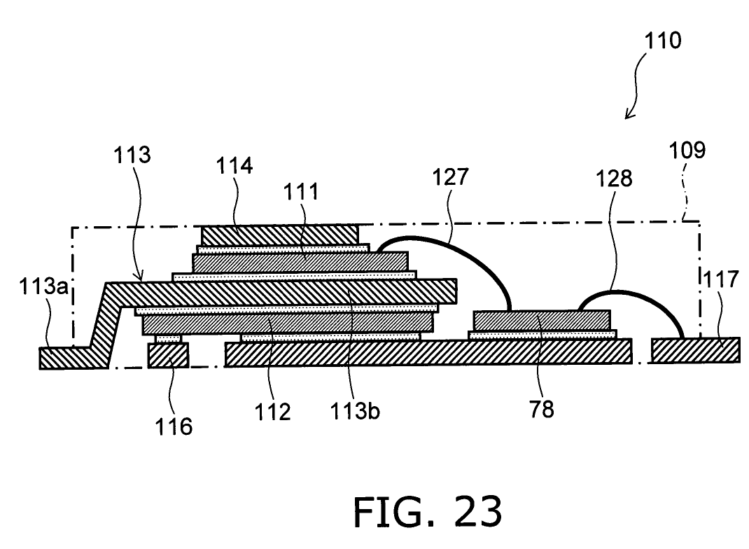

FIG. 23 is a cross section schematically illustrating the cross-sectional structure of the relevant part of a semiconductor device 110 of this example.

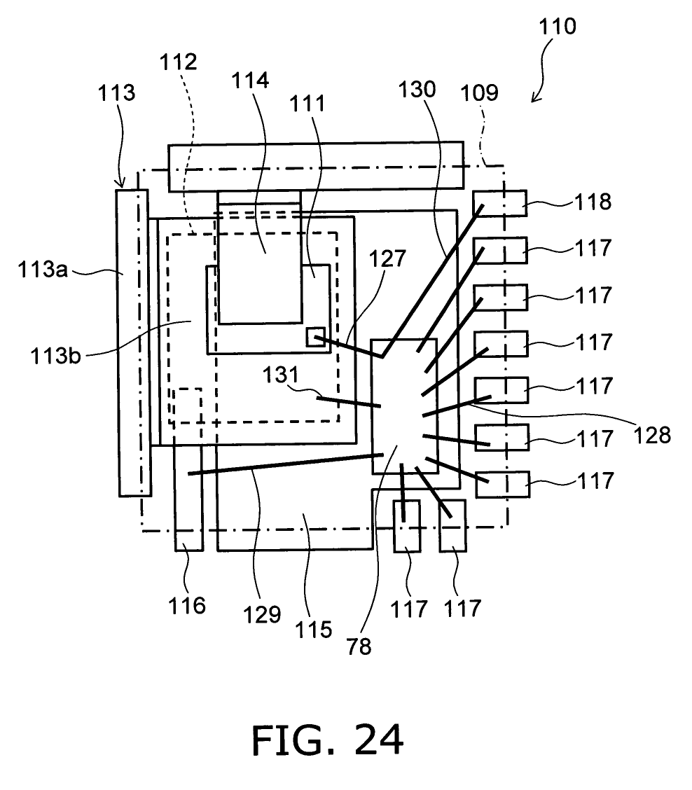

FIG. 24 is a plan view showing the internal structure of the semiconductor device 110.

The first semiconductor chip 111 includes a first MIS transistor Q1. The first semiconductor chip 111 is mounted on a lead frame 113 with its first face (lower face in FIG. 23) being opposed to one face (upper face in FIG. 23) of the island portion 113b of the lead frame 113. The lead frame 113 is made of conductor such as copper or copper alloy, for example.

The source electrode of the first MIS transistor Q1 is exposed on the first face of the first semiconductor chip 111.

The source electrode is bonded to the one face of the island portion 113b of the lead frame 113 via solder, for example. The source electrode of the first MIS transistor Q1 may be bonded to the lead frame 113 by conductive bonding material other than solder, or by ultrasonic bonding that utilizes vibrational friction between the bonding surfaces due to application of ultrasonic waves.

The second semiconductor chip 112 includes a second MIS transistor Q2. The second semiconductor chip 112 is mounted on the lead frame 113 with its first face (upper face in FIG. 23) being opposed to the other face (lower face in FIG. 23) of the island portion 113b of the lead frame 113.

The drain electrode of the second MIS transistor Q2 is exposed on the first face of the second semiconductor chip 112. The drain electrode is bonded to the other face of the island portion 113b of the lead frame 113 via solder, for example. The drain electrode of the second MIS transistor Q2 may be bonded to the lead frame 113 by conductive bonding material other than solder, or by ultrasonic bonding that utilizes vibrational friction between the bonding surfaces due to application of ultrasonic waves.

As described above, the first semiconductor chip 111 and the second semiconductor chip 112 are mounted on the top and bottom faces of the island portion 113b of the conductive lead frame 113, respectively. The source electrode of the first MIS transistor Q1 and the drain electrode of the second MIS transistor Q2 are electrically connected to each other with the lead frame 113 being used as a common potential.

The potential of the lead frame 113 corresponds to the potential of the connecting node Lₓ of the source electrode of the first MIS transistor Q1 and the drain electrode of the second MIS transistor Q2 in the circuit shown in FIG. 13. The lead frame 113 has an end portion 113a, which functions as an output terminal of the semiconductor device 110 and is connected to a print wiring board or other external circuit.

The drain electrode of the first MIS transistor Q1 is exposed on a second face (upper face in FIG. 23) of the first semiconductor chip 111. A first lead 114 is bonded opposite to the second face of the first semiconductor chip 111 by ultrasonic bonding, for example, and thereby the drain electrode of the first MIS transistor Q1 is electrically connected to the first lead 114. The first lead 114 is made of conductor such as copper or copper alloy, for example. The bonding between the drain electrode of the first MIS transistor Q1 and the first lead 114 is not limited to ultrasonic bonding, but may use conductive bonding material such as solder.

The first lead 114 has an end portion, which is connected to the input voltage supply Vᵢₙ shown in FIG. 13 via the print wiring board and the like.

The source electrode of the second MIS transistor Q2 is exposed on a second face (lower face in FIG. 23) of the second semiconductor chip 112. A second lead 115 is bonded opposite to the second face of the second semiconductor chip 112 by ultrasonic bonding, for example, and thereby the source electrode of the second MIS transistor Q2 is electrically connected to the second lead 115. The second lead 115 is made of conductor such as copper or copper alloy, for example. The bonding between the source electrode of the second MIS transistor Q2 and the second lead 115 is not limited to ultrasonic bonding, but may use conductive bonding material such as solder. The second lead 115 is connected to ground via the print wiring board and the like.

On the inner face (upper face) of the second lead 115, a control IC 78 is mounted on a portion that is not used for bonding the second semiconductor chip 112. The control IC 78 is mounted on the second lead 115 by the known die bonding method using conductive paste or a resin adhesive. The control IC 78 controls the switching operation of the first MIS transistor Q1 and the second MIS transistor Q2.

The gate electrode of the second MIS transistor Q2 is also exposed on the second face of the second semiconductor chip 112. A third lead 116 is bonded opposite to the second face of the second semiconductor chip 112 by ultrasonic bonding, for example, and thereby the gate electrode of the second MIS transistor Q2 is electrically connected to the third lead 116. The third lead 116 is made of conductor such as copper or copper alloy, for example. The bonding between the gate electrode of the second MIS transistor Q2 and the third lead 116 is not limited to ultrasonic bonding, but may use conductive bonding material such as solder.

A fourth lead 118 (see FIG. 24) is provided on the bottom face of the semiconductor device 110. The fourth lead 118 is connected to a pad formed on the upper face (the face on the opposite side of the mounting surface) of the control IC 78 via a bonding wire 130. The gate electrode of the first MIS transistor Q1 formed in the first semiconductor chip 111 is led out on the upper face of the first semiconductor chip 111 as a pad, which is connected to the pad formed on the upper face of the control IC 78 via a bonding wire 127. Hence the gate electrode of the first MIS transistor Q1 is connected to the control IC 78 via the bonding wire 127, and further connected to the fourth lead 118 via the control IC 78 and the bonding wire 130.

One end of a bonding wire 129 is bonded to the inner face (upper face) of the third lead 116. The other end of the bonding wire 129 is bonded to the pad formed on the upper face of the control IC 78. In this way, the gate electrode of the second MIS transistor Q2 formed in the second semiconductor chip 112 is connected to the control IC 78.

Furthermore, the control IC 78 is connected to the lead frame 113 via a bonding wire 131. Moreover, a plurality of leads 117 are provided on the bottom face of the semiconductor device 110. Each lead 117 is connected to the pad formed on the upper face of the control IC 78 via a bonding wire 128.

The island portion 113b of the lead frame 113, the first semiconductor chip 111, the second semiconductor chip 112, the control IC 78, and the bonding wires are sealed with a resin sealant 109 such as epoxy resin, for example.

The bottom face (outer face) of the second lead 115, third lead 116, fourth lead 118, and leads 117 provided on the bottom face of the semiconductor device 110 is exposed from the resin sealant 109, and can be connected to an external circuit via this exposed surface.

Likewise, the end portion of the first lead 114 and the end portion 113a of the lead frame 113 are also exposed from the resin sealant 109, and can be connected to an external circuit via this exposed surface.

The outer face (upper face) of the first lead 114 is exposed from the resin sealant 109. A heat radiating plate (not shown) is bonded to this exposed surface via solder, or an adhesive having high thermal conductivity, for example. The heat radiating plate is made of material having high thermal conductivity such as aluminum, for example.

As described above, in this example as well, the source electrode of the first MIS transistor Q1 and the drain electrode of the second MIS transistor Q2 are bonded to the top and bottom faces of the conductive lead frame 113, respectively, and thereby the source electrode of the first MIS transistor Q1 and the drain electrode of the second MIS transistor Q2 are electrically connected to each other. Accordingly, the wiring length between the first MIS transistor Q1 and the second MIS transistor Q2 is decreased and the associated resistance is lowered as compared to connection via bonding wires. Therefore the parasite inductance in this wiring and the impedance due to this parasite inductance can be reduced. This allows for improvement of the efficiency of the DC-DC converter and reduction of EMI noise during high-frequency operation. In this example, total parasitic inductances through a main current path can be reduced. In particular, the reduction of the parasitic inductance Lₕₛ causes the improvement of the conversion efficiency of the DC-DC converter.

Furthermore, in this example, in addition to the first semiconductor chip 111 and the second semiconductor chip 112, the control IC 78 is also housed and modularized in the same package, which is advantageous to high-density packaging. Since the second lead 115 for leading out the source electrode of the second MIS transistor Q2 is also used as the support for mounting the control IC 78, the number of parts is decreased to allow for downsizing and cost reduction.

For a DC-DC converter, there is concern about noise associated with the high-frequency switching noise of the first MIS transistor Q1 and the second MIS transistor Q2. However, since the second lead 115, on which the control IC 78 is mounted, is connected to ground, the influence of noise on the control IC 78 can be reduced.

Besides the second MIS transistor Q2, the diode D1 shown in FIG. 13 is also formed in the second semiconductor chip 112. The specific structure of the chip is similar to that of the fifth example described above with reference to FIG. 12. The parasite component between the wirings of the second MIS transistor Q2 and the diode D1 can also be reduced by forming the second MIS transistor Q2 and the diode D1 in the same chip. Note that the diode D1 may be formed in the first semiconductor chip 111 together with the first MIS transistor Q1 in the case of the step-up DC-DC converter.

### Thirteenth Example

Next, a thirteenth example of the invention is described.

The semiconductor device of this example is also used as a DC-DC converter shown in FIG. 13, for example.

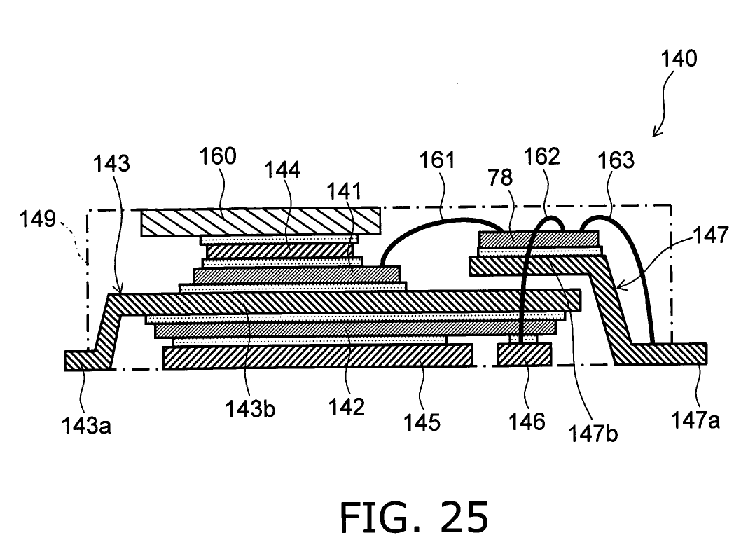

FIG. 25 is a cross section schematically illustrating the cross-sectional structure of the relevant part of a semiconductor device 140 of this example.

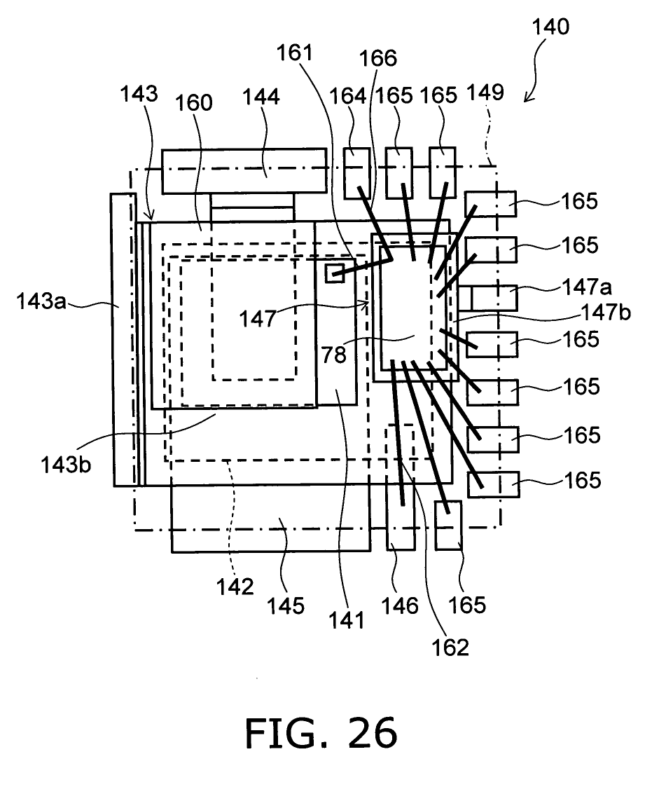

FIG. 26 is a plan view showing the internal structure of the semiconductor device 140.

The first semiconductor chip 141 includes a first MIS transistor Q1. The first semiconductor chip 141 is mounted on a first lead frame 143 with its first face (lower face in FIG. 25) being opposed to one face (upper face in FIG. 25) of the island portion 143b of the first lead frame 143. The first lead frame 143 is made of conductor such as copper or copper alloy, for example.

The source electrode of the first MIS transistor Q1 is exposed on the first face of the first semiconductor chip 141. The source electrode is bonded to the one face of the island portion 143b of the first lead frame 143 via solder, for example. The source electrode of the first MIS transistor Q1 may be bonded to the first lead frame 143 by conductive bonding material other than solder, or by ultrasonic bonding that utilizes vibrational friction between the bonding surfaces due to application of ultrasonic waves.

The second semiconductor chip 142 includes a second MIS transistor Q2. The second semiconductor chip 142 is mounted on the first lead frame 143 with its first face (upper face in FIG. 25) being opposed to the other face (lower face in FIG. 25) of the island portion 143b of the first lead frame 143.

The drain electrode of the second MIS transistor Q2 is exposed on the first face of the second semiconductor chip 142. The drain electrode is bonded to the other face of the island portion 143b of the first lead frame 143 via solder, for example. The drain electrode of the second MIS transistor Q2 may be bonded to the first lead frame 143 by conductive bonding material other than solder, or by ultrasonic bonding that utilizes vibrational friction between the bonding surfaces due to application of ultrasonic waves.

As described above, the first semiconductor chip 141 and the second semiconductor chip 142 are mounted on the top and bottom faces of the island portion 143b of the conductive first lead frame 143, respectively. The source electrode of the first MIS transistor Q1 and the drain electrode of the second MIS transistor Q2 are electrically connected to each other with the first lead frame 143 being used as a common potential.

The potential of the first lead frame 143 corresponds to the potential of the connecting node Lₓ of the source electrode of the first MIS transistor Q1 and the drain electrode of the second MIS transistor Q2 in the circuit shown in FIG. 13. The first lead frame 143 has an end portion 143a, which functions as an output terminal of the semiconductor device 140 and is connected to a print wiring board or other external circuit.

The drain electrode of the first MIS transistor Q1 is exposed on a second face (upper face in FIG. 25) of the first semiconductor chip 141. A first lead 144 is bonded opposite to the second face of the first semiconductor chip 141 by ultrasonic bonding, for example, and thereby the drain electrode of the first MIS transistor Q1 is electrically connected to the first lead 144. The first lead 144 is made of conductor such as copper or copper alloy, for example. The bonding between the drain electrode of the first MIS transistor Q1 and the first lead 144 is not limited to ultrasonic bonding, but may use conductive bonding material such as solder.

The first lead 144 has an end portion, which is connected to the input voltage supply Vᵢₙ shown in FIG. 13 via the print wiring board and the like.

In this example, a second lead frame 147 is provided for mounting a control IC 78. The island portion 147b of the second lead frame 147 is placed on the side of the island portion 143b of the first lead frame 143 where the first semiconductor chip 141 is mounted. The island portion 147b of the second lead frame 147 is spaced apart from the island portion 143b of the first lead frame 143.

The control IC 78 is mounted on the island portion 147b of the second lead frame 147 by the known die bonding method using conductive paste or a resin adhesive. The control IC 78 controls the switching operation of the first MIS transistor Q1 and the second MIS transistor Q2.

The source electrode of the second MIS transistor Q2 is exposed on a second face (lower face in FIG. 25) of the second semiconductor chip 142. A second lead 145 is bonded opposite to the second face of the second semiconductor chip 142 by ultrasonic bonding, for example, and thereby the source electrode of the second MIS transistor Q2 is electrically connected to the second lead 145. The second lead 145 is made of conductor such as copper or copper alloy, for example. The bonding between the source electrode of the second MIS transistor Q2 and the second lead 145 is not limited to ultrasonic bonding, but may use conductive bonding material such as solder. The second lead 145 is connected to ground via the print wiring board and the like.

The gate electrode of the second MIS transistor Q2 is also exposed on the second face of the second semiconductor chip 142. A third lead 146 is bonded opposite to the second face of the second semiconductor chip 142 by ultrasonic bonding, for example, and thereby the gate electrode of the second MIS transistor Q2 is electrically connected to the third lead 146. The third lead 146 is made of conductor such as copper or copper alloy, for example. The bonding between the gate electrode of the second MIS transistor Q2 and the third lead 146 is not limited to ultrasonic bonding, but may use conductive bonding material such as solder.

A fourth lead 164 (see FIG. 26) is provided on the bottom face of the semiconductor device 140. The fourth lead 164 is connected to a pad formed on the upper face (the face on the opposite side of the mounting surface) of the control IC 78 via a bonding wire 166. The gate electrode of the first MIS transistor Q1 formed in the first semiconductor chip 141 is led out on the upper face of the first semiconductor chip 141 as a pad, which is connected to the pad formed on the upper face of the control IC 78 via a bonding wire 161. Hence the gate electrode of the first MIS transistor Q1 is connected to the control IC 78 via the bonding wire 161, and further connected to the fourth lead 164 via the control IC 78 and the bonding wire 166.

One end of a bonding wire 162 is bonded to the inner face (upper face) of the third lead 146. The other end of the bonding wire 162 is bonded to the pad formed on the upper face of the control IC 78. In this way, the gate electrode of the second MIS transistor Q2 formed in the second semiconductor chip 142 is connected to the control IC 78.

Moreover, a plurality of leads 165 are provided on the bottom face of the semiconductor device 140. Each lead 165 is connected to the pad formed on the upper face of the control IC 78 via a bonding wire 163.

The island portion 143b of the lead frame 143, the first semiconductor chip 141, the second semiconductor chip 142, the control IC 78, and the bonding wires are sealed with a resin sealant 149 such as epoxy resin, for example.

The bottom face (outer face) of the second lead 145, third lead 146, fourth lead 164, leads 165, and the end portion 147a of the second lead frame 147 provided on the bottom face of the semiconductor device 140 is exposed from the resin sealant 149, and can be connected to an external circuit via this exposed surface.

Likewise, the end portion of the first lead 144 and the end portion 143a of the first lead frame 143 are also exposed from the resin sealant 149, and can be connected to an external circuit via this exposed surface.

The upper face of the first lead 144 is exposed from the resin sealant 149 without being covered. A heat radiating plate 160 shown in FIG. 25 is bonded to this exposed surface via solder, or an adhesive having high thermal conductivity, for example. The heat radiating plate 160 is made of material having high thermal conductivity such as aluminum, for example. The upper face of the heat radiating plate 160 is exposed from the resin sealant 149. A finned heat sink may be bonded to the upper face of the heat radiating plate 160.

As described above, in this example as well, the source electrode of the first MIS transistor Q1 and the drain electrode of the second MIS transistor Q2 are bonded to the top and bottom faces of the conductive first lead frame 143, respectively, and thereby the source electrode of the first MIS transistor Q1 and the drain electrode of the second MIS transistor Q2 are electrically connected to each other. Accordingly, the wiring length between the first MIS transistor Q1 and the second MIS transistor Q2 is decreased and the associated resistance is lowered as compared to connection via bonding wires. Therefore the parasite inductance in this wiring and the impedance due to this parasite inductance can be reduced. This allows for improvement of the efficiency of the DC-DC converter and reduction of EMI noise during high-frequency operation. In this example, total parasitic inductances through a main current path can be reduced. In particular, the reduction of the parasitic inductance Lₕₛ causes the improvement of the conversion efficiency of the DC-DC converter.

Furthermore, in addition to the first semiconductor chip 141 and the second semiconductor chip 142, the control IC 78 is also housed and modularized in the same package, which is advantageous to high-density packaging. According to the structure of this example, the first semiconductor chip 141, the second semiconductor chip 142, and the control IC 78 can be combined into a multichip module even if the second lead 145 cannot provide space for mounting the control IC 78.

In view of reducing the influence of noise on the control IC 78, the end portion 147a of the second lead frame 147 is preferably connected to ground.

For a DC-DC converter, there is concern about noise associated with the high-frequency switching noise of the first MIS transistor Q1 and the second MIS transistor Q2. However, since the second lead frame 147, on which the control IC 78 is mounted, is connected to ground, the influence of noise on the control IC 78 can be reduced.

Besides the second MIS transistor Q2, the diode D1 shown in FIG. 13 is also formed in the second semiconductor chip 142. The specific structure of the chip is similar to that of the fifth example described above with reference to FIG. 12. The parasite component between the wirings of the second MIS transistor Q2 and the diode D1 can also be reduced by forming the second MIS transistor Q2 and the diode D1 in the same chip. Note that the diode D1 may be formed in the first semiconductor chip 141 together with the first MIS transistor Q1 in the case of the step-up DC-DC converter.

1. A semiconductor device comprising:
a first semiconductor chip having a first MIS transistor of a first conductivity type, the first MIS transistor having a source electrode formed on a first face;
a second semiconductor chip having a second MIS transistor of the first conductivity type, the second MIS transistor having a drain electrode formed on a first face;
an IC chip which controls the first semiconductor chip and the second semiconductor chip; and
a resin sealant sealing the first semiconductor chip, the second semiconductor chip and the IC chip,
the source electrode of the first semiconductor chip and the drain electrode of the second semiconductor chip being bonded opposite to each other.

2. A semiconductor device according to claim 1, wherein a lead serving as an external connection terminal of the semiconductor chips is led out from a bonding surface of the source electrode of the first semiconductor chip and the drain electrode of the second semiconductor chip.

3. A semiconductor device according to claim 1, wherein a diode is formed in either of the first and second semiconductor chip.

4. (canceled)

5. A semiconductor device according to claim 1, wherein the first and second semiconductor chip are sealed in a resin sealant, and a heat radiating plate is provided on one or both of a face of the resin sealant opposite to a second face of the first semiconductor chip and a face of the resin sealant opposite to a second face of the second semiconductor chip.

6. A semiconductor device according to claim 3, wherein
the first MIS transistor has a drain electrode to be connected to an input terminal of a DC-DC converter,
the second MIS transistor has a source electrode to be connected to ground,
the diode has a cathode to be connected between a connecting node of the source electrode of the first MIS transistor and the drain electrode of the second MIS transistor and an output terminal of the DC-DC converter, and
the diode has an anode to be connected to ground.

7. A semiconductor device comprising:
a first semiconductor chip having a first MIS transistor of a first conductivity type, the first MIS transistor having a source electrode formed on a first face and a drain electrode formed on a second face opposite to the first face;
a second semiconductor chip having a second MIS transistor of the first conductivity type, the second MIS transistor having a drain electrode formed on a first face;
a lead frame, the source electrode of the first MIS transistor being bonded on one face of the lead frame whereby the first semiconductor chip is mounted, and the drain electrode of the second MIS transistor being bonded on the other face of the lead frame whereby the second semiconductor chip is mounted; and
a first lead bonded opposite to the drain electrode of the first MIS transistor.

8. A semiconductor device according to claim 7, further comprising:
a resin sealant for sealing the first semiconductor chip and the second semiconductor chip, wherein
at least a portion of a face of the first lead is exposed from the resin sealant, the face being on the other side of a face opposite to the first semiconductor chip.

9. A semiconductor device according to claim 8, wherein a heat radiating plate is bonded to the face of the first lead exposed from the resin sealant.

10. A semiconductor device according to claim 7, wherein
a source electrode and a gate electrode are formed on a second face on the other side of the first face of the second MIS transistor,
a second lead is bonded opposite to the source electrode of the second MIS transistor, and
a third lead is bonded opposite to the gate electrode of the second MIS transistor.

11. A semiconductor device according to claim 7, wherein
the drain electrode of the first MIS transistor is to be connected to an input terminal of a DC-DC converter,
the second MIS transistor has a source electrode to be connected to ground, and
a connecting node of the source electrode of the first MIS transistor and the drain electrode of the second MIS transistor is to be connected to an output terminal of the DC-DC converter.

12. A semiconductor device according to claim 11, wherein a diode having a cathode to be connected between the connecting node and the output terminal and an anode to be connected to ground is formed in either of the first semiconductor chip and the second semiconductor chip.

13. A semiconductor device comprising:
a first semiconductor chip having a first MIS transistor of a first conductivity type, the first MIS transistor having a source electrode formed on a first face and a drain electrode formed on a second face opposite to the first face;
a second semiconductor chip having a second MIS transistor of the first conductivity type, the second MIS transistor having a drain electrode formed on a first face;
a first lead frame, the source electrode of the first MIS transistor being bonded on one face of the first lead frame whereby the first semiconductor chip is mounted, and the drain electrode of the second MIS transistor being bonded on the other face of the first lead frame whereby the second semiconductor chip is mounted;
a first lead bonded opposite to the drain electrode of the first MIS transistor;
a control IC for controlling operation of the first MIS transistor and the second MIS transistor; and
a resin sealant for sealing the first semiconductor chip, the second semiconductor chip, and the control IC.

14. A semiconductor device according to claim 13, wherein
at least a portion of a face of the first lead is exposed from the resin sealant, the face being on the other side of a face opposite to the first semiconductor chip.

15. A semiconductor device according to claim 14, wherein a heat radiating plate is bonded to the face of the first lead exposed from the resin sealant.

16. A semiconductor device according to claim 13, wherein
a source electrode and a gate electrode are formed on a second face on the other side of the first face of the second MIS transistor,
a second lead is bonded opposite to the source electrode of the second MIS transistor, and
a third lead is bonded opposite to the gate electrode of the second MIS transistor.

17. A semiconductor device according to claim 16, wherein
the second lead is connected to ground, and
control IC is mounted on the second lead.

18. A semiconductor device according to claim 13, wherein
a second lead frame is provided on a side of the first lead frame where the first semiconductor chip is mounted, the second lead frame being spaced apart from the first lead frame, and
the control IC is mounted on the second lead frame.

19. A semiconductor device according to claim 13, wherein
the drain electrode of the first MIS transistor is to be connected to an input terminal of a DC-DC converter,
the second MIS transistor has a source electrode to be connected to ground,
a connecting node of the source electrode of the first MIS transistor and the drain electrode of the second MIS transistor is to be connected to an output terminal of the DC-DC converter, and
the control IC is to be connected to a gate electrode of the first MIS transistor and a gate electrode of the second MIS transistor.

20. A semiconductor device according to claim 19, wherein a diode having a cathode to be connected between the connecting node and the output terminal and an anode to be connected to ground is formed in either of the first semiconductor chip and the second semiconductor chip.

21. A semiconductor device according to claim 18, wherein the control IC is mounted on a face of the second lead frame, the face being on the other side of a face opposite to the first lead frame.
